(19) United States
(12) Patent Application Publication
(10) Pub. No.: US 2026/0344084 A1
(43) Pub. Date: Oct. 29, 2026

(54) PHOTODETECTION DEVICE, ELECTRONIC DEVICE, AND METHOD FOR MANUFACTURING PHOTODETECTION DEVICE

(71) Applicant: SONY SEMICONDUCTOR SOLUTIONS CORPORATION, KANAGAWA (JP)

(72) Inventors: SHINICHI YOSHIDA, KANAGAWA (JP); NAOTO HOJO, KANAGAWA (JP)

(21) Appl. No.: 19/107,038

(22) PCT Filed: Aug. 23, 2023
(86) PCT No.: PCT/JP2023/030367

§ 371 Date: Feb. 27, 2025

(30) Foreign Application Priority Data
Sep. 6, 2022 (JP) 2022-141709

(51) Int. Cl. H10F 39/00; H10F 39/12; H10F 39/18

(52) U.S. Cl. CPC H10F 39/807; H10F 39/014; H10F 39/18; H10F 39/199

(57) ABSTRACT

Provided is a photodetection device capable of improving a saturation charge amount Qs of a photoelectric conversion unit. Specifically, the semiconductor device includes: a semiconductor substrate on which a plurality of photoelectric conversion units is formed; and an element isolation portion including a trench portion formed between the photoelectric conversion units in the semiconductor substrate, a semiconductor layer disposed in the trench portion and covering a side wall surface of the trench portion, and a functional layer disposed in a space inside the trench portion covered with the semiconductor layer. In addition, the photoelectric conversion unit has an N type semiconductor region in a region in contact with the semiconductor layer. Then, the semiconductor layer has a P type impurity concentration of 1e16/cm³ or less, and the functional layer is a layer that induces a hole on a side of the functional layer of the semiconductor layer.

### TECHNICAL FIELD

The present disclosure relates to a photodetection device, an electronic device, and a method for manufacturing a photodetection device.

### BACKGROUND ART

Conventionally, a photodetection device has been proposed in which a trench portion is provided between photoelectric conversion units, and a P type semiconductor layer by epitaxial growth is disposed in the trench portion (see, for example, Patent Document 1). In the photodetection device described in Patent Document 1, a P type semiconductor layer functions as a hole pinning layer, and generation of dark current on a side wall surface of the trench portion is suppressed.

### CITATION LIST

### Patent Document

Patent Document 1: Japanese Patent Application Laid-Open No. 2012-38981

### SUMMARY OF THE INVENTION

### Problems to be Solved by the Invention

In such a photodetection device, it is required to further improve the amount of charge (hereinafter, also referred to as a “saturated charge amount Qs”) that can be accumulated in a photoelectric conversion unit.

An object of the present disclosure is to provide a photodetection device, an electronic device, and a method for manufacturing the photodetection device capable of improving a saturation charge amount Qs of a photoelectric conversion unit.

### Solutions to Problems

A photodetection device of the present disclosure includes: (a) a semiconductor substrate on which a plurality of photoelectric conversion units is formed; and (b) an element isolation portion including a trench portion formed between the photoelectric conversion units in the semiconductor substrate, a Semiconductor layer disposed in the trench portion and covering a side wall surface of the trench portion, and a functional layer disposed in a space inside the trench portion covered with the semiconductor layer, in which (c) the photoelectric conversion unit has an N type semiconductor region in a region in contact with the semiconductor layer, (d) the semiconductor layer has a P type impurity concentration of 1e16/cm³ or less, and (e) the functional layer is a layer that induces a hole on a side of the functional layer of the semiconductor layer.

Another photodetection device of the present disclosure includes: (a) a semiconductor substrate on which a plurality of photoelectric conversion units is formed; and (b) an element isolation portion including a trench portion formed between the photoelectric conversion units in the semiconductor substrate, and a P type solid-phase diffusion layer disposed in the trench portion and covering a side wall surface of the trench portion, in which (c) the photoelectric conversion unit has an N type Semiconductor region in a region in contact with the P type solid-phase diffusion layer, and (d) the P type solid-phase diffusion layer has an N type impurity concentration of 1e16/cm³ or less.

Another photodetection device of the present disclosure includes: (a) a semiconductor substrate on which a plurality of photoelectric conversion units is formed; and (b) an element isolation portion including a trench portion formed between the photoelectric conversion units in the semiconductor substrate, an N type epitaxial growth layer disposed in the trench portion and covering a side wall surface of the trench portion, and a P type epitaxial growth layer disposed in a space inside the trench portion covered with the N type epitaxial growth layer and in contact with the N type epitaxial growth layer, in which (c) the N type epitaxial growth layer has a P type impurity concentration of 1e16/cm³ or less, and (d) the P type epitaxial growth layer has an N type impurity concentration of 1e16/cm³ or less.

An electronic device of the present disclosure includes a photodetection device, the photodetection device including: (a) a semiconductor substrate on which a plurality of photoelectric conversion units is formed; and (b) an element isolation portion including a trench portion formed between the photoelectric conversion units in the semiconductor substrate, a semiconductor layer disposed in the trench portion and covering a side wall surface of the trench portion, and a functional layer disposed in a space inside the trench portion covered with the semiconductor layer, in which (c) the photoelectric conversion unit has an N type semiconductor region in a region in contact with the semiconductor layer, (d) the semiconductor layer has a P type impurity concentration of 1e16/cm³ or less, and (e) the functional layer is a layer that induces a hole on a side of the functional layer of the semiconductor layer.

Another electronic device of the present disclosure including a photodetection device, the photodetection device including: (a) a semiconductor substrate on which a plurality of photoelectric conversion units is formed; and (b) an element isolation portion including a trench portion formed between the photoelectric conversion units in the semiconductor substrate, and a P type solid-phase diffusion layer disposed in the trench portion and covering a side wall surface of the trench portion, in which (c) the photoelectric conversion unit has an N type semiconductor region in a region in contact with the P type solid-phase diffusion layer, and (d) the P type solid-phase diffusion layer has an N type impurity concentration of 1e16/cm³ or less.

Another electronic device of the present disclosure includes a photodetection device, the photodetection device including: (a) a semiconductor substrate on which a plurality of photoelectric conversion units is formed; and (b) an element isolation portion including a trench portion formed between the photoelectric conversion units in the semiconductor substrate, an N type epitaxial growth layer disposed in the trench portion and covering a side wall surface of the trench portion, and a P type epitaxial growth layer disposed in a space inside the trench portion covered with the N type epitaxial growth layer and in contact with the N type epitaxial growth layer, in which (c) the N type epitaxial growth layer has a P type impurity concentration of 1e16/cm³ or less, and (d) the P type epitaxial growth layer has an N type impurity concentration of 1e16/cm³ or less.

A method for manufacturing a photodetection device of the present disclosure includes: (a) a step of forming a trench portion in a semiconductor substrate; (b) a step of forming an epitaxial growth layer having an impurity concentration of 1e16/cm³ or less on a side wall surface of the trench portion by epitaxial growth; and (c) a step of doping P type impurities into the epitaxial growth layer from inside the trench portion by solid-phase diffusion.

Another method for manufacturing a photodetection device of the present disclosure includes: (a) a step of forming a trench portion in a semiconductor substrate; (b) a step of forming an N type epitaxial growth layer having a P type impurity concentration of 1e16/cm³ or less on a side wall surface of the trench portion by epitaxial growth while adding N type impurities; and (c) a step of forming a P type epitaxial growth layer having an N type impurity concentration of 1e16/cm³ or less on a surface of the N type epitaxial growth layer on a center side in a width direction of the trench portion by epitaxial growth while adding P type impurities.

### BRIEF DESCRIPTION OF DRAWINGS

FIG. 1 is a diagram illustrating an overall configuration of a solid-state imaging device according to a first embodiment.

FIG. 2 is a diagram illustrating a cross-sectional configuration of the solid-state imaging device taken along line A-A in FIG. 1.

FIG. 3 is a diagram illustrating a cross-sectional configuration of the solid-state imaging device in a case where the region B in FIG. 2 is enlarged.

FIG. 4 is a diagram illustrating a distribution of an N type impurity concentration at a position indicated by line C-C in FIG. 3.

FIG. 5 is a diagram illustrating a cross-sectional configuration of a solid-state imaging device in a case where a semiconductor layer is P type.

FIG. 6A is a diagram illustrating a method for manufacturing the solid-state imaging device.

FIG. 6B is a diagram illustrating the method for manufacturing the solid-state imaging device.

FIG. 6C is a diagram illustrating the method for manufacturing the solid-state imaging device.

FIG. 6D is a diagram illustrating the method for manufacturing the solid-state imaging device.

FIG. 6E is a diagram illustrating the method for manufacturing the solid-state imaging device.

FIG. 6F is a diagram illustrating the method for manufacturing the solid-state imaging device.

FIG. 6G is a diagram illustrating the method for manufacturing the solid-state imaging device.

FIG. 6H is a diagram illustrating the method for manufacturing the solid-state imaging device.

FIG. 7A is a diagram illustrating a method for manufacturing a solid-state imaging device according to a modification.

FIG. 7B is a diagram illustrating the method for manufacturing the solid-state imaging device according to the modification.

FIG. 7C is a diagram illustrating the method for manufacturing the solid-state imaging device according to the modification.

FIG. 7D is a diagram illustrating the method for manufacturing the solid-state imaging device according to the modification.

FIG. 8 is a diagram illustrating a cross-sectional configuration of a solid-state imaging device according to a second embodiment.

FIG. 9 is a diagram illustrating a cross-sectional configuration of the solid-state imaging device in a case where the region D in FIG. 8 is enlarged.

FIG. 10 is a diagram illustrating a cross-sectional configuration of a solid-state imaging device according to a modification.

FIG. 11 is a diagram illustrating a cross-sectional configuration of the solid-state imaging device in a case where the region E in FIG. 10 is enlarged.

FIG. 12 is a diagram illustrating a cross-sectional configuration of a solid-state imaging device according to a third embodiment.

FIG. 13 is a diagram illustrating a cross-sectional configuration of the solid-state imaging device in a case where the region F in FIG. 12 is enlarged.

FIG. 14 is a diagram illustrating a potential distribution.

FIG. 15 is a diagram illustrating a cross-sectional configuration of a solid-state imaging device in a case of including a P type semiconductor region.

FIG. 16 is a diagram illustrating a potential distribution.

FIG. 17A is a diagram illustrating a method for forming an element isolation portion.

FIG. 17B is a diagram illustrating the method for forming the element isolation portion.

FIG. 17C is a diagram illustrating the method for forming the element isolation portion.

FIG. 17D is a diagram illustrating the method for forming the element isolation portion.

FIG. 17E is a diagram illustrating the method for forming the element isolation portion.

FIG. 17F is a diagram illustrating the method for forming the element isolation portion.

FIG. 17G is a diagram illustrating the method for forming the element isolation portion.

FIG. 18A is a diagram illustrating a method for forming an element isolation portion.

FIG. 18B is a diagram illustrating the method for forming the element isolation portion.

FIG. 18C is a diagram illustrating the method for forming the element isolation portion.

FIG. 18D is a diagram illustrating the method for forming the element isolation portion.

FIG. 18E is a diagram illustrating the method for forming the element isolation portion.

FIG. 18F is a diagram illustrating the method for forming the element isolation portion.

FIG. 18G is a diagram illustrating the method for forming the element isolation portion.

FIG. 18H is a diagram illustrating the method for forming the element isolation portion.

FIG. 18I is a diagram illustrating the method for forming the element isolation portion.

FIG. 19 is a diagram illustrating a cross-sectional configuration of a solid-state imaging device according to a modification.

FIG. 20 is a diagram illustrating a cross-sectional configuration of the solid-state imaging device in a case where the region G in FIG. 19 is enlarged.

FIG. 21 is a diagram illustrating a method for forming an element isolation portion.

FIG. 22A is a diagram illustrating the method for forming the element isolation portion.

FIG. 22B is a diagram illustrating the method for forming the element isolation portion.

FIG. 23 is a diagram illustrating a cross-sectional configuration of a solid-state imaging device according to a modification.

FIG. 24 is a diagram illustrating a cross-sectional configuration of the solid-state imaging device in a case where the region H in FIG. 23 is enlarged.

FIG. 25 is a diagram illustrating a method for forming an element isolation portion.

FIG. 26A is a diagram illustrating the method for forming the element isolation portion.

FIG. 26B is a diagram illustrating the method for forming the element isolation portion.

FIG. 27 is a diagram illustrating a cross-sectional configuration of a solid-state imaging device according to a modification.

FIG. 28 is a diagram illustrating a cross-sectional configuration of the solid-state imaging device in a case where the region I in FIG. 27 is enlarged.

FIG. 29 is a diagram illustrating a method for forming an element isolation portion.

FIG. 30A is a diagram illustrating the method for forming the element isolation portion.

FIG. 30B is a diagram illustrating the method for forming the element isolation portion.

FIG. 31 is a diagram illustrating a cross-sectional configuration of a solid-state imaging device according to a fourth embodiment.

FIG. 32 is a diagram illustrating a cross-sectional configuration of the solid-state imaging device in a case where the region J in FIG. 31 is enlarged.

FIG. 33A is a diagram illustrating a method for forming an element isolation portion.

FIG. 33B is a diagram illustrating the method for forming the element isolation portion.

FIG. 34A is a diagram illustrating the method for forming the element isolation portion.

FIG. 34B is a diagram illustrating the method for forming the element isolation portion.

FIG. 34C is a diagram illustrating the method for forming the element isolation portion.

FIG. 35 is a diagram illustrating an overall configuration of an electronic device according to a fifth embodiment.

### MODE FOR CARRYING OUT THE INVENTION

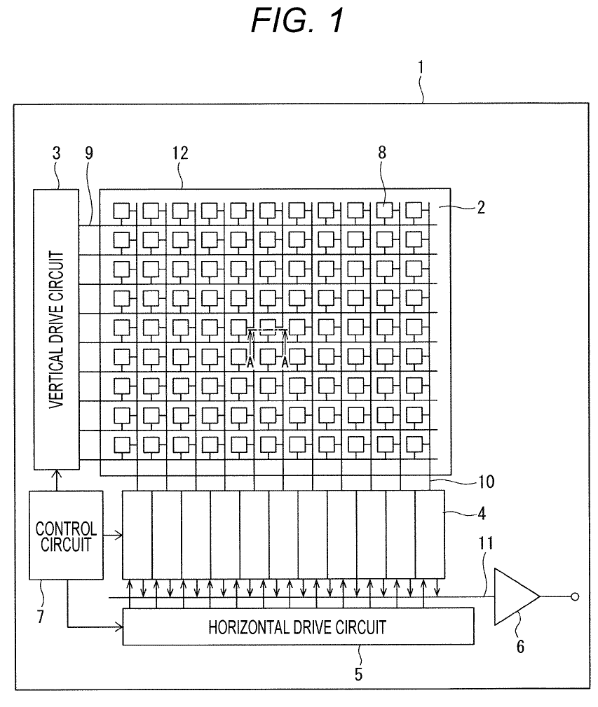

Hereinafter, an example of a photodetection device, an electronic device, and a method for manufacturing the photodetection device according to an embodiment of the present disclosure will be described with reference to FIGS. 1 to 35. Embodiments of the present disclosure will be described in the following order. Note that, the present disclosure is not limited to the following examples. Furthermore, the effects described herein are illustrative and not restrictive, and there may be additional effects.
1. First Embodiment: Solid-State Imaging Device
   1-1 Overall Configuration of Solid-State Imaging Device
   1-2 Configuration of Main Part
   1-3 Method for Manufacturing Solid-State Imaging Device
   1-4 Modification
2. Second Embodiment: Solid-State Imaging Device
   2-1 Configuration of Main Part
   2-2 Modification
3. Third Embodiment: Solid-State Imaging Device
   3-1 Configuration of Main Part
   3-2 Method for Manufacturing Solid-State Imaging Device
   3-3 Modification
4. Fourth Embodiment: Solid-State Imaging Device
   4-1 Configuration of Main Part
   4-2 Method for Manufacturing Solid-State Imaging Device
   4-3 Modification
5. Fifth Embodiment: Application Example to Electronic Device

### 1. FIRST EMBODIMENT: SOLID-STATE IMAGING DEVICE

### 1-1 Overall Configuration of Solid-State Imaging Device

A solid-state imaging device 1 (in a broad sense, a “photodetection device”) according to a first embodiment of the present disclosure will be described. FIG. 1 is a diagram illustrating an overall configuration of the solid-state imaging device 1 according to the first embodiment.

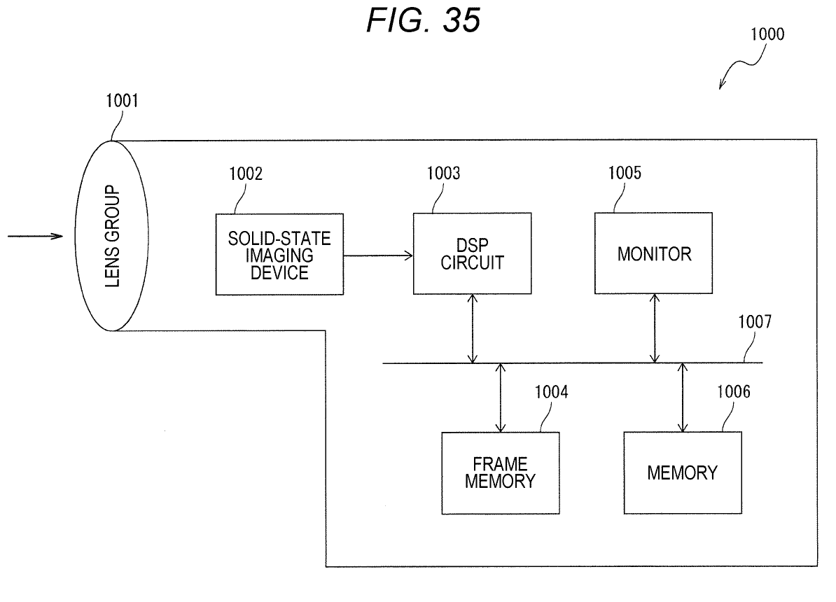

The solid-state imaging device 1 in FIG. 1 is a back-illuminated complementary metal oxide semiconductor (CMOS) image sensor. As illustrated in FIG. 35, the solid-state imaging device 1 (1002) captures image light (incident light) from a subject via a lens group 1001, converts an amount of the incident light forming an image on an imaging surface into an electric signal in units of pixels, and outputs the electric signal as a pixel signal.

As illustrated in FIG. 1, the solid-state imaging device 1 includes a pixel region 2, a vertical drive circuit 3, a column signal processing circuit 4, a horizontal drive circuit 5, an output circuit 6, and a control circuit 7.

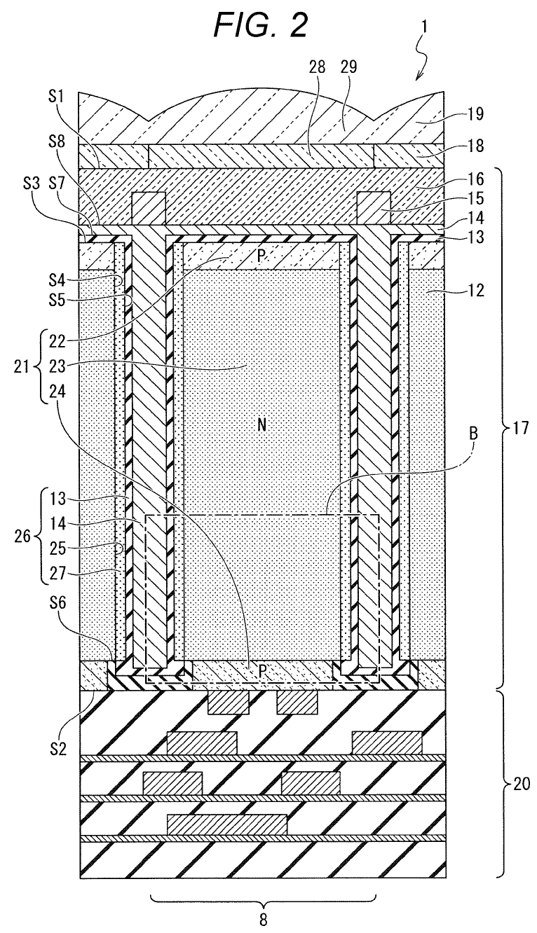

The pixel region 2 includes a plurality of pixels 8 arranged in a two-dimensional array. The pixel 8 includes a photoelectric conversion unit 21 illustrated in FIG. 2 and a plurality of pixel transistors. Examples of the plurality of pixel transistors include four MOS transistors including a transfer transistor, a reset transistor, an amplification transistor, and a selection transistor.

The vertical drive circuit 3 includes, for example, a shift register, selects a desired pixel drive wire 9, supplies a pulse for driving the pixels 8 to the selected pixel drive wire 9, and drives each pixel 8 row by row. That is, the vertical drive circuit 3 selectively scans each pixel 8 in the pixel region 2 sequentially in the vertical direction in units of rows, and supplies a pixel signal based on a signal charge generated according to the amount of received light in the photoelectric conversion unit 21 of each pixel 8 to the column signal processing circuit 4 through the vertical signal line 10.

The column signal processing circuit 4 is arranged, for example, for each column of the pixels 8, and performs signal processing such as noise removal for each pixel column on signals output from the pixels 8 of one row. For example, the column signal processing circuit 4 performs signal processing such as correlated double sampling (CDS) for removing a fixed pattern noise unique to pixels, and analog-digital (AD) conversion.

The horizontal drive circuit 5 includes, for example, a shift register, sequentially outputs a horizontal scanning pulse to the column signal processing circuit 4, sequentially selects each of the column signal processing circuits 4, and causes each of the column signal processing circuits 4 to output a pixel signal subjected to signal processing to a horizontal signal line 11.

The output circuit 6 performs signal processing on the pixel signals sequentially supplied from each of the column signal processing circuits 4 through the horizontal signal line 11, and outputs the pixel signals. As the signal processing, for example, buffering, black level adjustment, column variation correction, various types of digital signal processing, and the like can be used.

The control circuit 7 generates a clock signal that is a reference for operations and a control signal, for the vertical drive circuit 3, the column signal processing circuits 4, the horizontal drive circuit 5, and the like, on the basis of a vertical synchronization signal, a horizontal synchronization signal, and a master clock signal. Then, the control circuit 7 outputs the generated clock signal and control signal to the vertical drive circuit 3, the column signal processing circuits 4, the horizontal drive circuit 5, and the like.

### 1-2 Configuration of Main Part

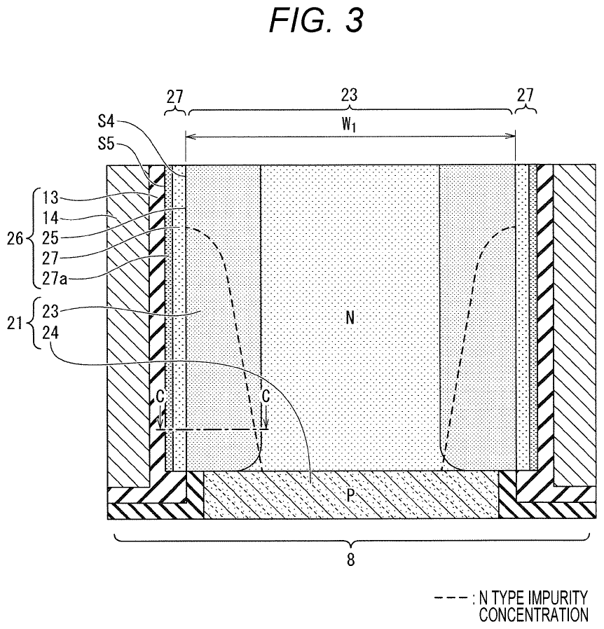

Next, a detailed structure of the solid-state imaging device 1 is described. FIG. 2 is a diagram illustrating a cross-sectional configuration of the solid-state imaging device 1 taken along line A-A in FIG. 1. Furthermore, FIG. 3 is a diagram illustrating a cross-sectional configuration of the solid-state imaging device 1 in a case where the region B in FIG. 2 is enlarged.

As illustrated in FIGS. 2 and 3, in the solid-state imaging device 1, a light receiving layer 17 formed by laminating a semiconductor substrate 12, a fixed charge film 13 (in a broad sense, a “functional layer”), an insulating film 14, a light shielding film 15, and a planarizing film 16 in this order is disposed. In addition, a color filter layer 18 and a microlens array 19 are arranged in this order on a surface of the light receiving layer 17 on the planarizing film 16 side (hereinafter, also referred to as a “back surface S1”). Furthermore, a wiring layer 20 is disposed on a surface (hereinafter, also referred to as a “surface S2”) of the light receiving layer 17 on the semiconductor substrate 12 side.

The semiconductor substrate 12 includes, for example, silicon (Si). In the semiconductor substrate 12, the photoelectric conversion unit 21 is formed in each region of each pixel 8. That is, the plurality of photoelectric conversion units 21 is arranged in a two-dimensional array on the semiconductor substrate 12. In the photoelectric conversion unit 21, a P type semiconductor region 22 containing P type impurities and a P type semiconductor region 24 containing P type impurities are formed on each of the light incident surface (hereinafter, also referred to as a “back surface S3”) side and the front surface S2 side of the semiconductor substrate 12. Furthermore, an N type semiconductor region 23 continuous in the thickness direction of the semiconductor substrate 12 is formed between the P type semiconductor region 22 and the P type semiconductor region 24 so as to be in contact with a semiconductor layer 27 surrounding the periphery of the photoelectric conversion unit 21. That is, the photoelectric conversion unit 21 has the N type semiconductor region 23 in a region in contact with the semiconductor layer 27. The semiconductor layer 27 is a layer covering the side wall surface S4 of the trench portion 25 formed between the photoelectric conversion units 21. As the P type impurities, for example, boron (B) can be employed. Further, as the N type impurities, for example, phosphorus (P) and arsenic (As) can be employed. The photoelectric conversion unit 21 constitutes a photodiode by PN junction of a junction surface between the P type semiconductor region 22 and the N type semiconductor region 23 and a junction surface between the P type semiconductor region 24 and the N type semiconductor region 23. Then, photoelectric conversion is performed to generate a charge corresponding to the amount of received light. In addition, the photoelectric conversion unit 21 accumulates charges generated by photoelectric conversion in the N type semiconductor region 23.

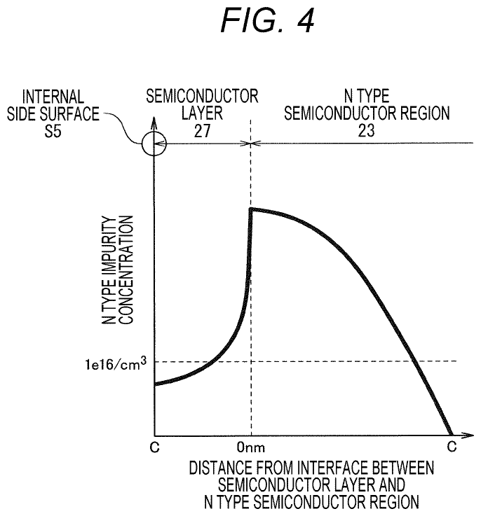

In addition, as illustrated in FIGS. 3 and 4, the N type impurity concentration of the N type semiconductor region 23 is higher on the trench portion 25 side than on the central portion side of the photoelectric conversion unit 21, and has a peak of the N type impurity concentration at the interface between the trench portion 25 (semiconductor layer 27) and the N type semiconductor region 23. As a result, in the N type semiconductor region 23, the N type impurity concentration in the vicinity of the interface can be increased, and the amount of charge (that is, the saturation charge amount Qs) that can be accumulated in the photoelectric conversion unit 21 can be increased. In FIG. 3, the N type semiconductor region 23 is represented in a darker color as the N type impurity concentration is higher. Further, in FIG. 3, a curve indicating the N type impurity concentration is indicated by a broken line in superposition with the N type semiconductor region 23. FIG. 4 is a diagram illustrating a distribution of an N type impurity concentration at a position indicated by line C-C in FIG. 3. Further, the N type impurity concentration of the N type semiconductor region 23 is constant in the thickness direction of the semiconductor substrate 12. Therefore, the peak of the N type impurity concentration at the interface between the trench portion 25 (semiconductor layer 27) and the N type semiconductor region 23 is continuous in the thickness direction of the semiconductor substrate 12. As a result, each of the amount of charge that can be accumulated on the back surface S3 side of the semiconductor substrate 12 and the amount of charge that can be accumulated on the front surface S2 side can be increased, and the saturation charge amount Qs can be further increased. Note that the distribution of the impurity concentration of the N type semiconductor region 23 and the semiconductor layer 27 illustrated in FIG. 4 can be obtained by, for example, performing analysis by Nano-SIMS (Secondary Ion Mass Spectrometry).

Further, in the semiconductor substrate 12, the trench portion 25 is formed between the adjacent photoelectric conversion units 21. The trench portion 25 is formed from the front surface S2 to the back surface S3 of the semiconductor substrate 12 along the side surface of the photoelectric conversion unit 21. That is, the trench portions 25 are formed in a lattice shape in the semiconductor substrate 12 so as to surround each of the photoelectric conversion units 21. In addition, the trench portion 25 forms the element isolation portion 26 together with the semiconductor layer 27, the fixed charge film 13, and the insulating film 14.

The semiconductor layer 27 covering the side wall surface S4 of the trench portion 25 is disposed inside the trench portion 25. The semiconductor layer 27 is formed so as to surround each photoelectric conversion unit 21 when viewed from the thickness direction of the semiconductor substrate 12. As the semiconductor layer 27, for example, a non-doped semiconductor layer formed at a timing different from that of the semiconductor substrate 12, such as a non-doped epitaxial growth layer, can be adopted. The epitaxial growth layer is a semiconductor layer formed by epitaxially growing a semiconductor crystal. By using such an epitaxial growth layer, the P type impurity concentration of the semiconductor layer 27 is 1e16/cm³ or less (low numerical value). By lowering the P type impurity concentration, as illustrated in FIG. 3, the semiconductor layer 27 can suppress diffusion of the P type impurities from the semiconductor layer 27 into the photoelectric conversion unit 21, and can suppress erosion of the N type semiconductor region 23 in the photoelectric conversion unit 21. Therefore, it is possible to suppress a decrease in the saturation charge amount Qs of the photoelectric conversion unit 21. That is, the saturation charge amount Qs of the photoelectric conversion unit 21 can be improved.

In addition, as illustrated in FIG. 4, the N type impurity concentration of the semiconductor layer 27 is set to 1e16/cm³ or less on a surface (hereinafter, also referred to as an “internal side surface S5”) farther from the side wall surface S4 of the trench portion 25 in the surface of the semiconductor layer 27. As will be described later, at the time of manufacturing the solid-state imaging device 1, a semiconductor layer (for example, an epitaxial growth layer) having an impurity concentration of 1e16/cm³ or less is formed as the semiconductor layer 27. Therefore, almost all the N type impurities in the Semiconductor layer 27 are diffused from the N type semiconductor region 23. Therefore, the N type impurity concentration (1e16/cm³ or less) of the semiconductor layer 27 is realized by adjusting the thickness and the like of the N type semiconductor region 23 and the semiconductor layer 27. The layer thickness (film thickness) of the semiconductor layer 27 can be, for example, 10 nm or more. By lowering the N type impurity concentration, a hole inductive layer 27a can be formed by the fixed charge film 13 on the internal side surface S5 side of the semiconductor layer 27 as described later. As a material of the semiconductor layer 27, for example, the same material as that of the semiconductor substrate 12 (for example, silicon (Si)) can be adopted.

Further, the internal side surface S5 of the semiconductor layer 27 is covered with the fixed charge film 13. That is, the fixed charge film 13 is disposed along the internal side surface S5 of the semiconductor layer 27 in the space inside the trench portion 25 covered with the semiconductor layer 27. As a material of the fixed charge film 13, for example, a material capable of generating a negative fixed charge and realizing pinning by being deposited on the semiconductor layer 27 can be adopted. For example, a high refractive index material film or a high dielectric film having a negative fixed charge can be adopted. Specific examples thereof include an oxide or nitride (Al₂O₃, HfO₂, Ta₂O₅, and the like) containing at least one element of aluminum (Al), hafnium (Hf), tantalum (Ta), zirconium (Zr), and titanium (Ti). As a result, as illustrated in FIG. 3, holes (positive holes) are induced on the fixed charge film 13 side (internal side surface S5 side) of the semiconductor layer 27 by the fixed charge film 13 to form a portion in a high hole concentration state (hereinafter, also referred to as a “hole inductive layer 27a”), and pinning of the side wall of the trench portion 25 is realized. This pinning can suppress dark current generated on the side wall of the trench portion 25. That is, it can be said that the fixed charge film 13 is a layer that induces holes on the fixed charge film 13 side (internal side surface S5 side) of the semiconductor layer 27.

In addition, the insulating film 14 is embedded in a groove-shaped space inside the trench portion 25 covered with the semiconductor layer 27 and the fixed charge film 13. As a material of the insulating film 14, for example, silicon oxide (SiO₂) or silicon nitride (SiN) can be adopted. According to 25, the insulating film 14 suppresses occurrence of electrical color mixture due to crosstalk in which the charge photoelectrically converted by one photoelectric conversion unit 21 moves to the other photoelectric conversion unit 21 between the adjacent photoelectric conversion units 21.

The fixed charge film 13 covers the bottom surface of the trench portion 25 and the back surface S3 of the semiconductor substrate 12 together with the semiconductor layer 27. In addition, the insulating film 14 covers the light incident surface (hereinafter, also referred to as a “back surface S7”) of the fixed charge film 13 together with embedding in the trench portion 25.

The light shielding film 15 is disposed on the light incident surface (hereinafter, also referred to as a “back surface S8”) side of the insulating film 14, and is formed so as to open the light incident surface of each photoelectric conversion unit 21. As a material of the light shielding film 15, for example, aluminum (Al), tungsten (W), or copper (Cu) can be adopted.

The planarizing film 16 is disposed on the back surface S8 side of the insulating film 14, and continuously covers the back surface S8 and the light shielding film 15 such that the back surface S1 side of the light receiving layer 17 is a flat surface. As a material of the insulating film 14, for example, silicon oxide (SiO₂) or silicon nitride (SIN) can be adopted.

The color filter layer 18 includes a plurality of color filters 28 formed on the back surface S1 side of the planarizing film 16 and arranged corresponding to the photoelectric conversion unit 21. That is, one color filter 28 is formed for one photoelectric conversion unit 21. The plurality of color filters 28 includes a plurality of types of color filters that transmit light of a predetermined wavelength included in light collected by a microlens 29. As a result, each of the color filters 28 transmits light having a predetermined wavelength corresponding to the color filter 28, and causes the transmitted light to enter the photoelectric conversion unit 21.

The microlens array 19 includes a plurality of microlenses 29 formed on the back surface S9 side (light receiving surface side) of the color filter layer 18 and arranged corresponding to the photoelectric conversion unit 21. That is, one microlens 29 is formed for one photoelectric conversion unit 21. Thus, each of the microlenses 29 condenses image light (incident light) from a subject, and causes the condensed incident light to enter the corresponding photoelectric conversion unit 21 via the color filter 28.

The wiring layer 20 is disposed on the front surface S2 side of the semiconductor substrate 12. The wiring layer 20 includes an interlayer insulating film and wiring (not illustrated) laminated in a plurality of layers via the interlayer insulating film. Then, the wiring layer 20 drives the pixel transistor of each pixel 8 via the plurality of layers of wiring.

In the solid-state imaging device 1 having the above configuration, light is emitted from the back surface S3 side of the semiconductor substrate 12, the emitted light passes through the microlens 29 and the color filter 28, and the transmitted light is photoelectrically converted by the photoelectric conversion unit 21 to generate signal charges. Then, the generated signal charge is output as a pixel signal from the vertical signal line 10 in FIG. 1 formed by the wiring of the wiring layer 20.

Furthermore, in the solid-state imaging device 1, the fixed charge film 13 forms the hole inductive layer 27a on the fixed charge film 13 side of the semiconductor layer 27, and pinning of the side wall of the trench portion 25 is realized. Then, this pinning suppresses dark current generated on the side wall of the trench portion 25.

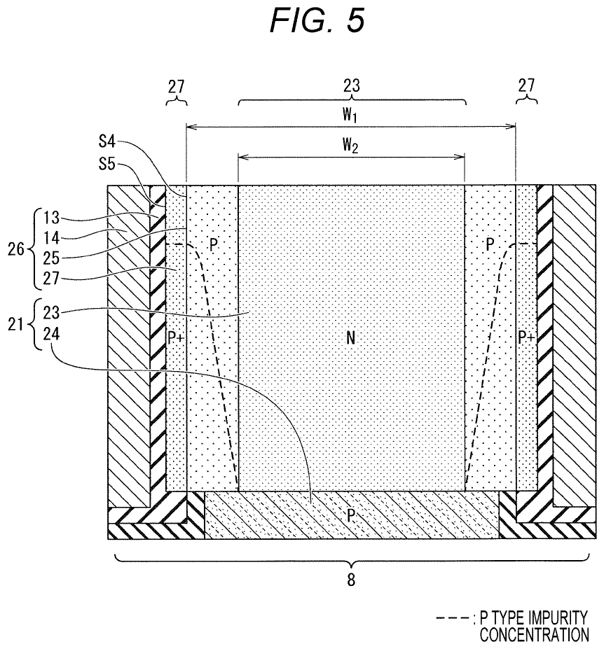

Here, for example, as illustrated in FIG. 5, in a case where the semiconductor layer 27 is a P+ type semiconductor layer 27 having a relatively high P type impurity concentration, there is a possibility that the P type impurities are diffused from the P+ type semiconductor layer 27 into the photoelectric conversion unit 21, and the N type semiconductor region 23 in the photoelectric conversion unit 21 is eroded. FIG. 5 illustrates a case where the N type semiconductor region 23 is eroded by P type impurities, and the width decreases from W₁ to W₂. Therefore, there is a possibility that the saturation charge amount Qs of the photoelectric conversion unit 21 decreases. In FIG. 5, a portion having a higher P type impurity concentration is indicated by a darker color. Further, in FIG. 5, a curve indicating a P type impurity concentration is indicated by a broken line in superposition with the P+type semiconductor layer 27.

Furthermore, in a case where the solid-state imaging device 1 is made to have multiple pixels, the pixels 8 are miniaturized. However, in the solid-state imaging device 1 illustrated in FIG. 5, in a case where the pixels 8 are miniaturized, in addition to the reduction of the N type semiconductor region 23 due to the diffusion of the P type impurities described above, the reduction of the N type semiconductor region 23 due to the miniaturization of the pixels 8 also occurs, and thus, there is a possibility that it is difficult to secure the necessary saturation charge amount Qs.

On the other hand, in the solid-state imaging device 1 according to the first embodiment, as illustrated in FIG. 3, the semiconductor layer 27 is configured such that the P type impurity concentration is 1e16/cm³ or less. Therefore, diffusion of P type impurities from the semiconductor layer 27 into the photoelectric conversion unit 21 can be suppressed, and erosion of the N type semiconductor region 23 in the photoelectric conversion unit 21 can be suppressed. FIG. 3 illustrates a case where the N type semiconductor region 23 is not eroded by P type impurities and the width thereof is maintained at W₁. Therefore, it is possible to suppress a decrease in the amount of charge (saturation charge amount Qs) that can be accumulated in the photoelectric conversion unit 21. That is, the saturation charge amount Qs of the photoelectric conversion unit 21 can be improved. Furthermore, even in a case where the pixels 8 are miniaturized, the N type semiconductor region 23 is not reduced due to diffusion of P type impurities. Therefore, a necessary saturation charge amount Qs can be secured, and the solid-state imaging device 1 can be made to have multiple pixels relatively easily.

### 1-3 Method for Manufacturing Solid-State Imaging Device

Next, a method for manufacturing the solid-state imaging device 1 according to the first embodiment will be described.

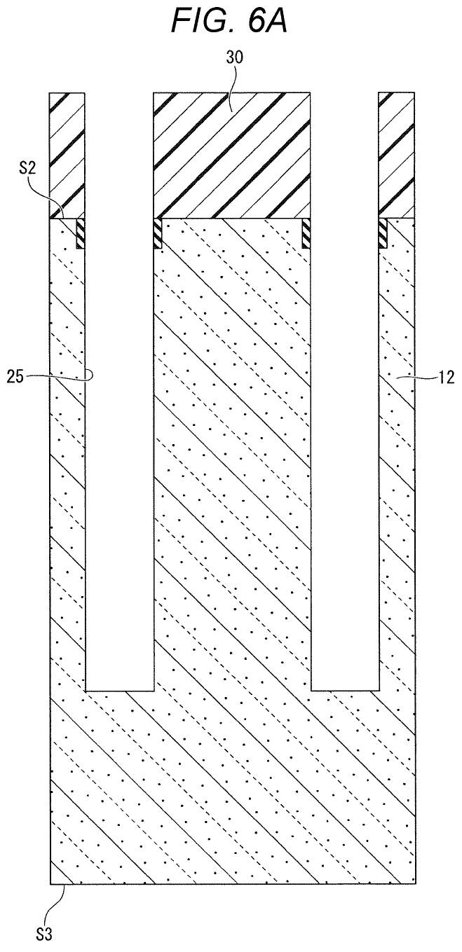

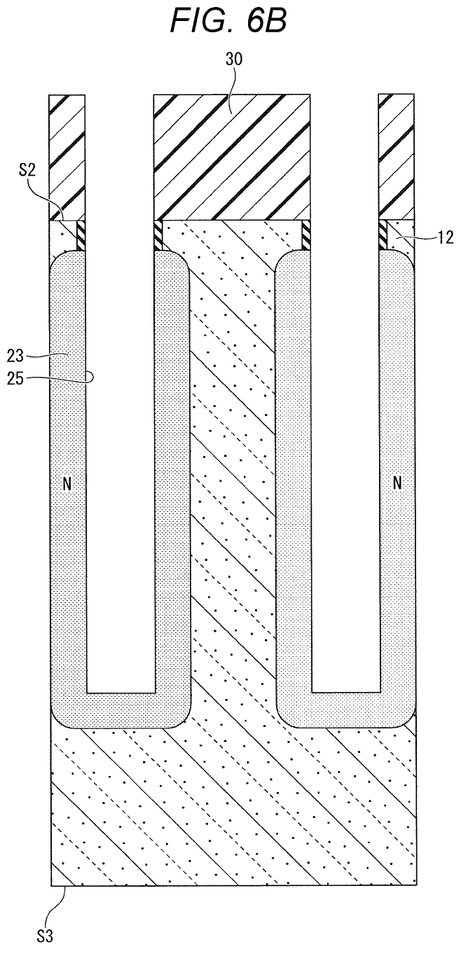

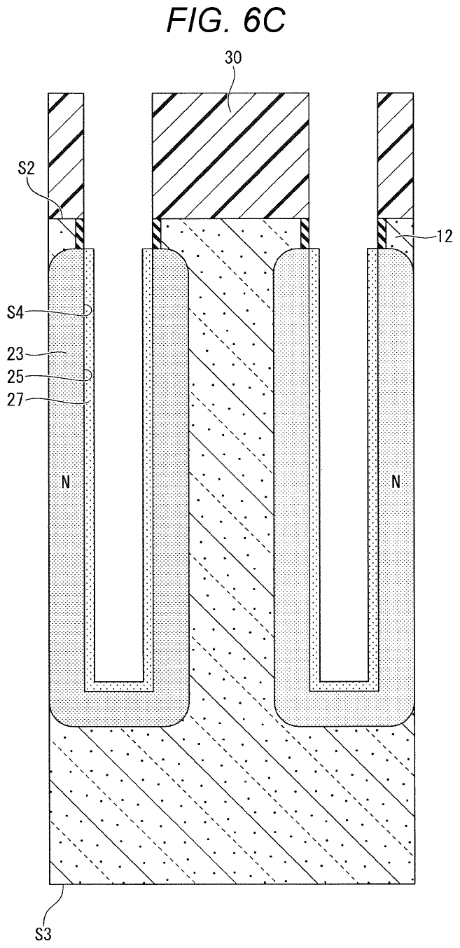

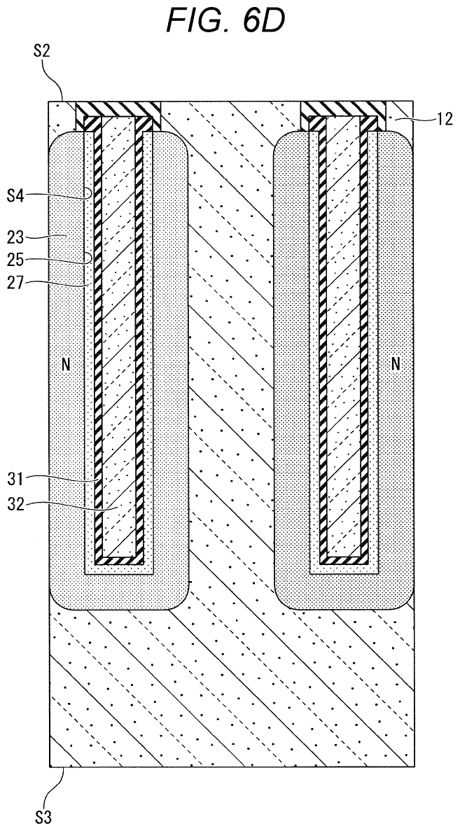

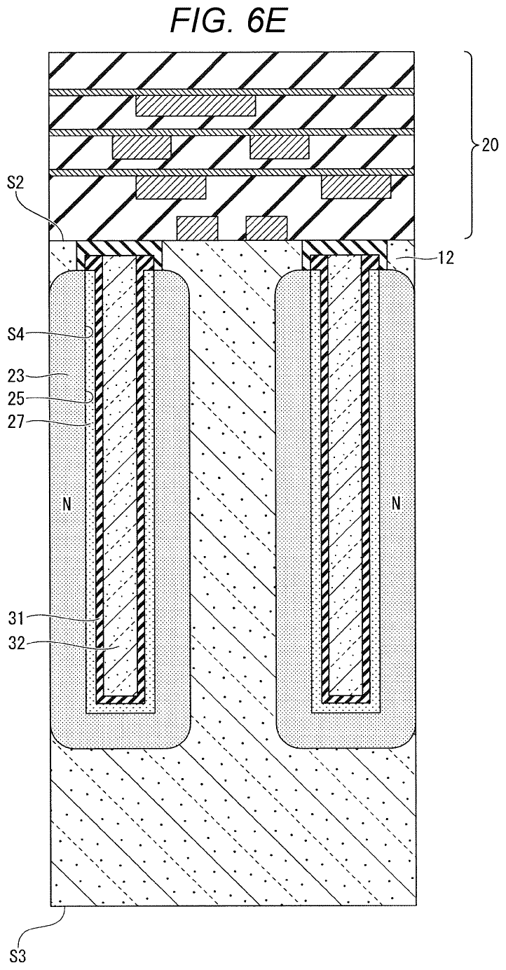

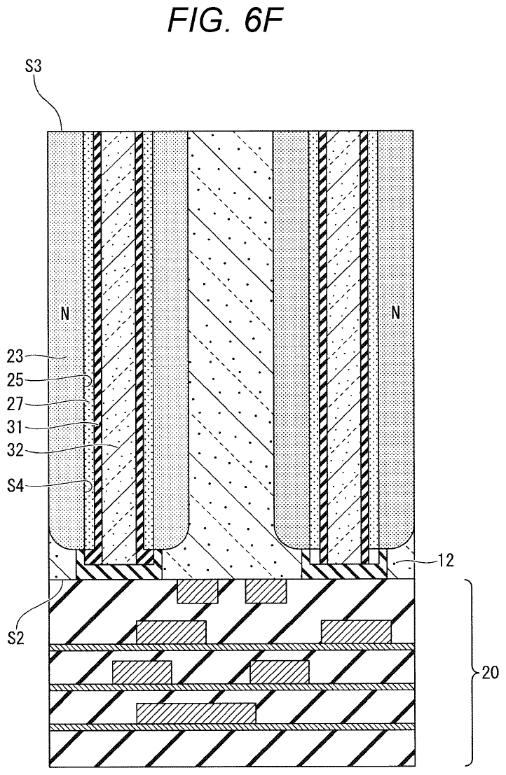

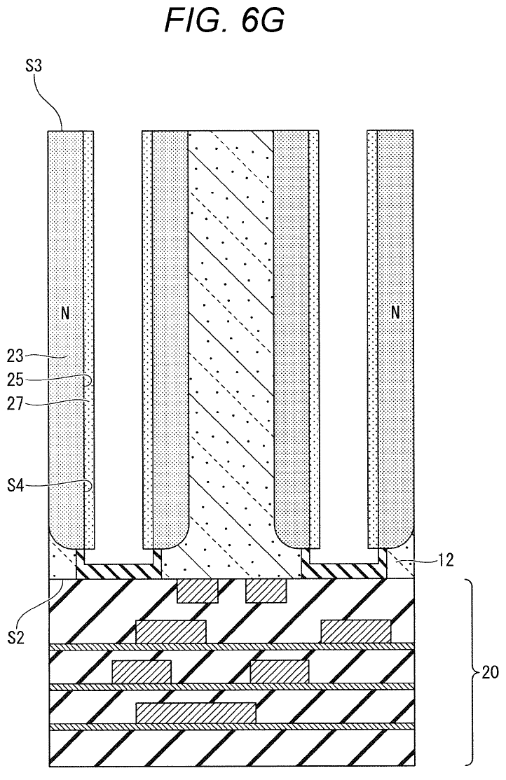

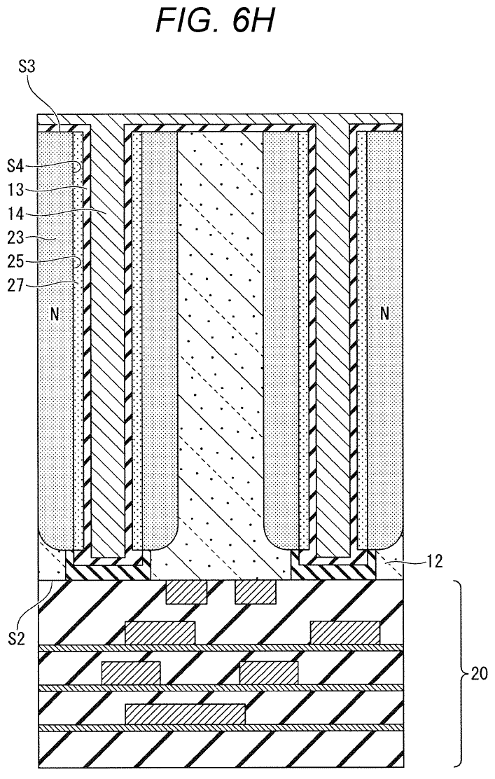

First, as illustrated in FIG. 6A, a mask 30 having openings at positions where the trench portions 25 are to be formed is formed on the front surface S2 of the semiconductor substrate 12. Subsequently, anisotropic dry etching is performed through the mask 30 to form the trench portions 25. As described above, by forming the trench portions 25 in the FEOL process (front-end-of-line process), processing damage at the time of forming the trench portions 25 can be recovered using heat treatment performed in a later process, and white spot and dark current can be suppressed. Subsequently, the N type semiconductor region 23 of the photoelectric conversion unit 21 is formed on the side wall surface S4 of the trench portion 25 using a conformal doping technology as illustrated in FIG. 6B. As described above, since the trench portion 25 is formed by the FEOL process, a process of introducing N type impurities from the inside of the trench portion 25 can be applied to the formation of the N type semiconductor region 23. As a method for doping the N type impurities, for example, a solid-phase diffusion method, plasma doping, and an ion implant implantation method can be adopted. Note that, in FIG. 6B, in the N type semiconductor region 23, only a portion indicated by a dark color in FIG. 3 (only a portion having a large N type impurity concentration) is indicated by a dot. In addition, similar expressions are used in FIGS. 6C to 6H.

Subsequently, as illustrated in FIG. 6C, a semiconductor crystal (for example, silicon (Si)) is epitaxially grown on the side wall surface S4 of the trench portion 25, and the semiconductor layer 27 is formed in the trench portion 25 so as to cover the side wall surface S4 and the bottom surface of the trench portion 25. As the semiconductor layer 27, an epitaxial growth layer having an impurity concentration of 1e16/cm³ or less is formed. Subsequently, as illustrated in FIG. 6D, silicon oxide (SiO) 31 and doped polysilicon 32 are embedded in this order in the space inside the trench portion 25 covered with the semiconductor layer 27. Subsequently, as illustrated in FIG. 6E, the wiring layer 20 is formed on the front surface S2 side of the semiconductor substrate 12. Subsequently, after the sensor substrate including the semiconductor substrate 12 and the wiring layer 20 is joined to a logic substrate (not illustrated), the semiconductor substrate 12 is polished from the back surface S3 side to be thinned as illustrated in FIG. 6F using a CMP technique.

Subsequently, as illustrated in FIG. 6G, the silicon oxide 31 and the doped polysilicon 32 are removed from the inside of the trench portion 25. Subsequently, as illustrated in FIG. 6H, the fixed charge film 13 and the insulating film 14 are formed in this order in the trench portion 25. Subsequently, as illustrated in FIG. 2, the light shielding film 15, the planarizing film 16, the color filter layer 18, and the microlens array 19 are formed in this order on the back surface S8 of the insulating film 14. As a result, the solid-state imaging device 1 according to the first embodiment is manufactured.

### 1-4 Modification

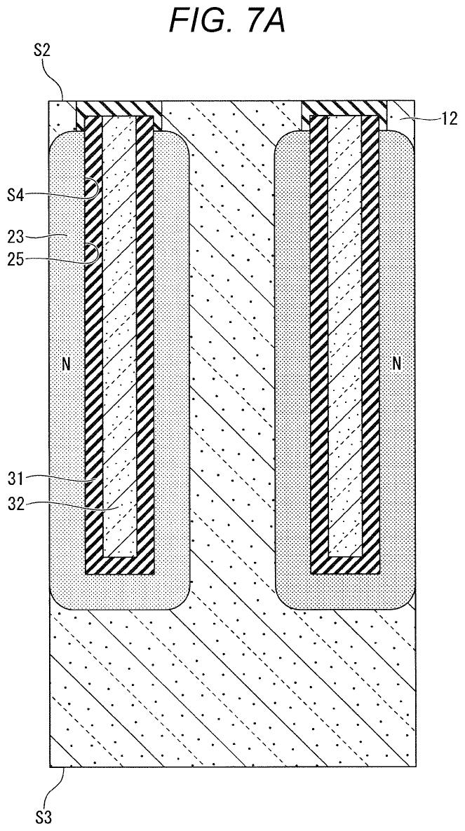

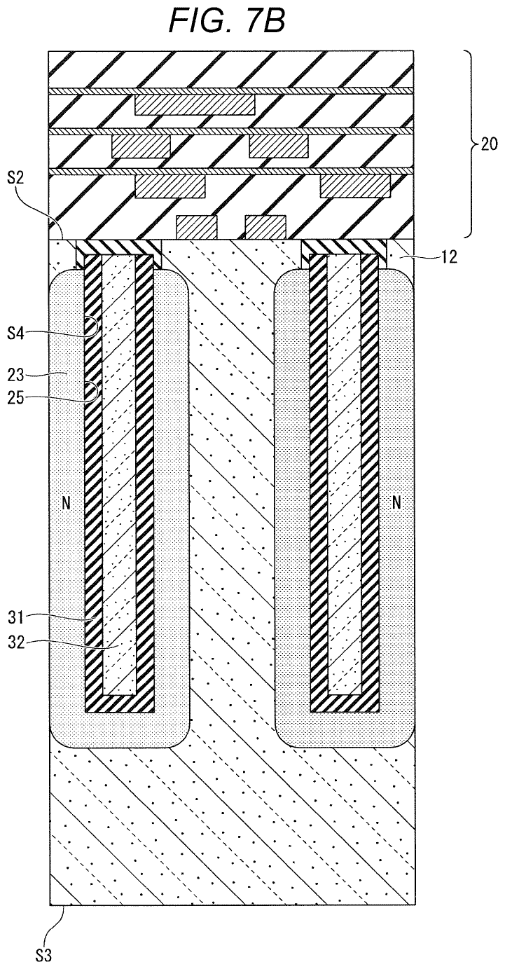

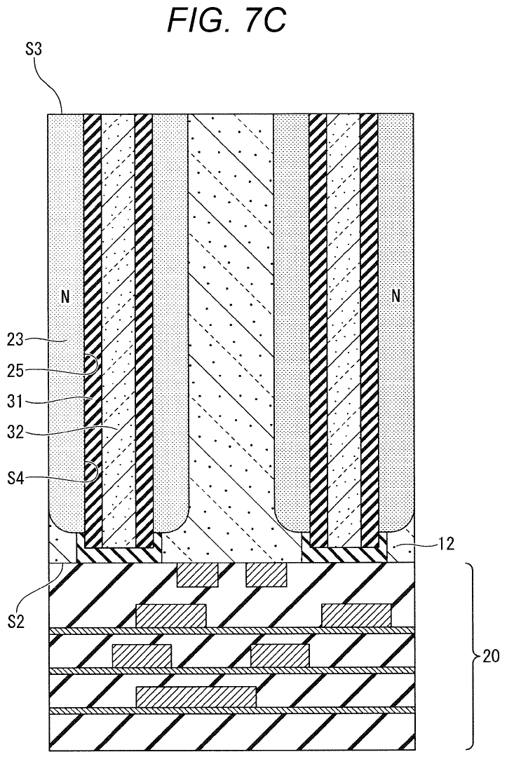

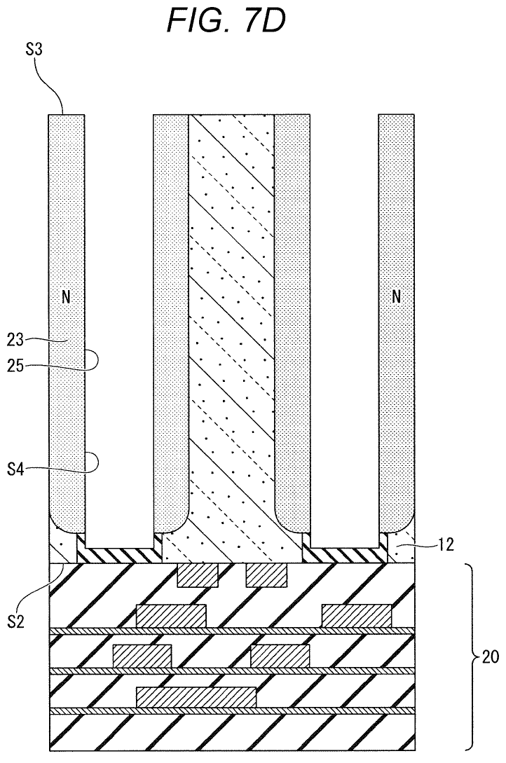

(1) Note that, in the first embodiment, an example has been described in which the semiconductor layer 37 is formed in a step (FEOL step) before the sensor substrate and the logic substrate are joined or the semiconductor substrate 12 is thinned, but other configurations can also be adopted. For example, it may be formed after the FEOL process. For example, first, after the above-described steps illustrated in FIGS. 6A and 6B are performed, as illustrated in FIG. 7A, the silicon oxide (SiO) 31 and the doped polysilicon 32 are embedded in the space inside the trench portion 25 in this order. Subsequently, as illustrated in FIG. 7B, the wiring layer 20 is formed on the front surface S2 side of the semiconductor substrate 12. Subsequently, after the sensor substrate including the semiconductor substrate 12 and the wiring layer 20 is joined to a logic substrate (not illustrated), as illustrated in FIG. 7C, the semiconductor substrate 12 is polished from the back surface S3 side to be thinned by using a chemical mechanical polishing (CMP) technique.

Subsequently, as illustrated in FIG. 7D, the silicon oxide (SiO) 31 and the doped polysilicon 32 are removed from the inside of the trench portion 25. Subsequently, as illustrated in FIG. 6G, a semiconductor crystal (for example, silicon (Si)) is epitaxially grown on the side wall surface S4 of the trench portion 25, and the semiconductor layer 27 is formed in the trench portion 25 so as to cover the side wall surface S4 and the bottom surface of the trench portion 25. Subsequently, as illustrated in FIG. 6H, the fixed charge film 13 and the insulating film 14 are formed in this order in the trench portion 25. Subsequently, as illustrated in FIG. 2, the light shielding film 15, the planarizing film 16, the color filter layer 18, and the microlens array 19 are formed in this order on the back surface S8 of the insulating film 14.

### 2. SECOND EMBODIMENT: SOLID-STATE IMAGING DEVICE

### 2-1 Configuration of Main Part

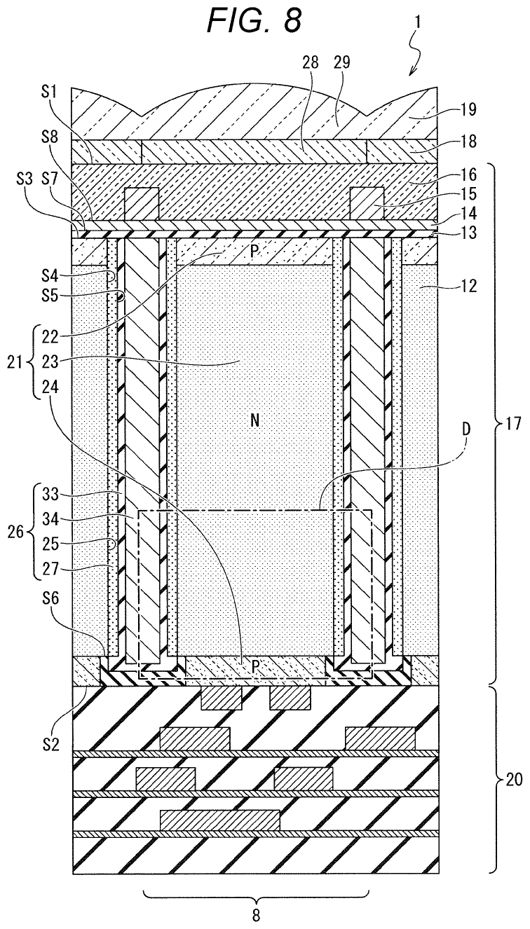

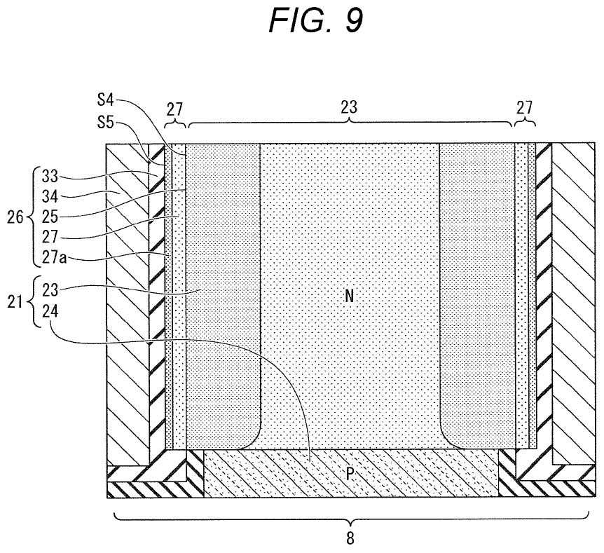

Next, a solid-state imaging device 1 according to a second embodiment of the present disclosure will be described. An overall configuration of the solid-state imaging device 1 according to the second embodiment is similar to that in FIG. 1, and thus illustration thereof will be omitted. FIG. 8 is a diagram illustrating a cross-sectional configuration of the solid-state imaging device 1 according to the second embodiment. Furthermore, FIG. 9 is a diagram illustrating a cross-sectional configuration of the solid-state imaging device 1 in a case where the region D in FIG. 8 is enlarged. In FIGS. 8 and 9, portions corresponding to FIGS. 2 and 3 are denoted by the same reference numerals, and redundant description is omitted.

As illustrated in FIGS. 8 and 9, the second embodiment is different from the first embodiment in that an insulating film 33 and a conductor portion 34 to which a negative bias voltage is applied are embedded in this order in a space inside a trench portion 25 instead of the fixed charge film 13 and the insulating film 14 illustrated in FIG. 2.

The internal side surface S5 of the semiconductor layer 27 is covered with the insulating film 33. As a result, the conductor portion 34 and the photoelectric conversion unit 21 (N type semiconductor region 23) are insulated by the insulating film 33. As a material of the insulating film 33, for example, silicon oxide (SiO) or a high dielectric constant insulating film can be adopted.

In addition, the conductor portion 34 is embedded in a groove-shaped space inside the trench portion 25 covered with the semiconductor layer 27 and the insulating film 33. That is, the conductor portion 34 is disposed along the internal side surface S5 of the semiconductor layer 27 via the insulating film 33. As a material of the conductor portion 34, for example, polysilicon to which boron (B) is added or a metal material can be adopted. In addition, a negative bias voltage is applied to the conductor portion 34. As a result, as illustrated in FIG. 9, holes (positive holes) are induced on the conductor portion 34 side (internal side surface S5 side) of the semiconductor layer 27 by the conductor portion 34 to form a portion (hole inducing layer 27a) in a high hole concentration state, and pinning of the side wall of the trench portion 25 is realized. This pinning can suppress dark current generated on the side wall of the trench portion 25. Examples of a method of applying the negative bias voltage to the conductor portion 34 include a method of supplying power from the logic substrate (not illustrated) side and a method of applying the negative bias voltage from the back surface S3 side of the semiconductor substrate 12.

### 2-2 Modification

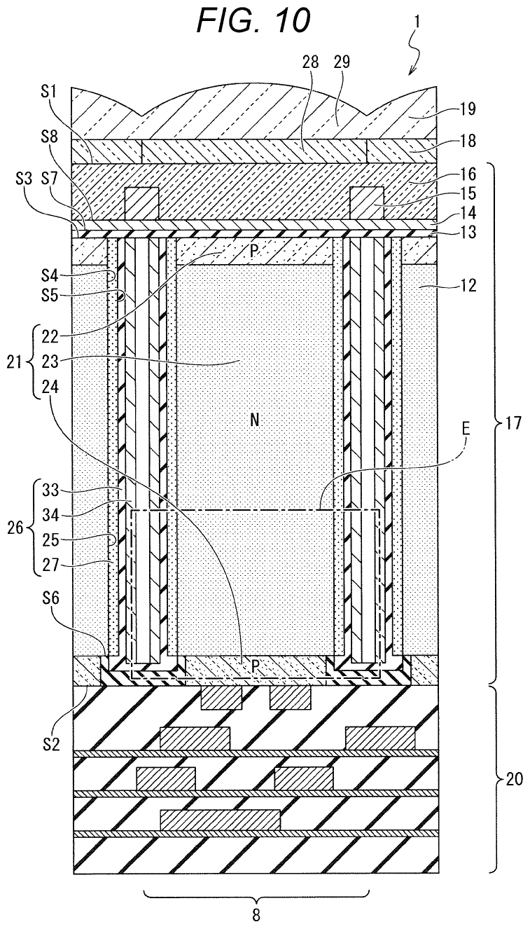

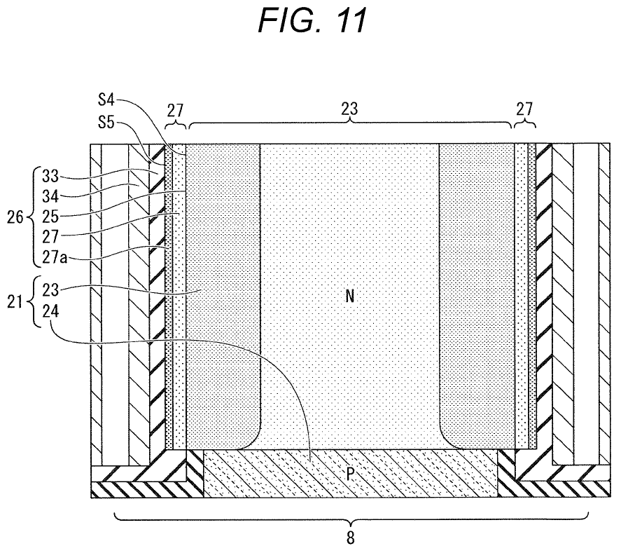

(1) Note that, in the second embodiment, an example in which the conductor portion 34 is embedded in the space inside the trench portion 25 has been described, but other configurations can also be adopted. For example, as illustrated in FIGS. 10 and 11, the conductor portion 34 may cover the side wall surface S4 of the trench portion 25 such that the side wall portion has a groove-shaped space formed by the conductor portion 34 inside the trench portion 25. Here, polysilicon has a property of absorbing light. Therefore, for example, in a case where the conductor portion 34 illustrated in FIGS. 8 and 9 is formed using polysilicon, that is, in a case where polysilicon is embedded (filled) in the space inside the trench portion 25, the quantum efficiency QE may decrease. On the other hand, in the present modification, the conductor portion 35 is formed so as to have a groove-shaped space inside the trench portion 25. Therefore, for example, in a case where the conductor portion 34 is formed using polysilicon, the amount of polysilicon can be reduced by the space inside the trench portion 25, and absorption of light by polysilicon can be suppressed. As a result, a decrease in the quantum efficiency QE can be suppressed.

### 3. THIRD EMBODIMENT: SOLID-STATE IMAGING DEVICE

### 3-1 Configuration of Main Part

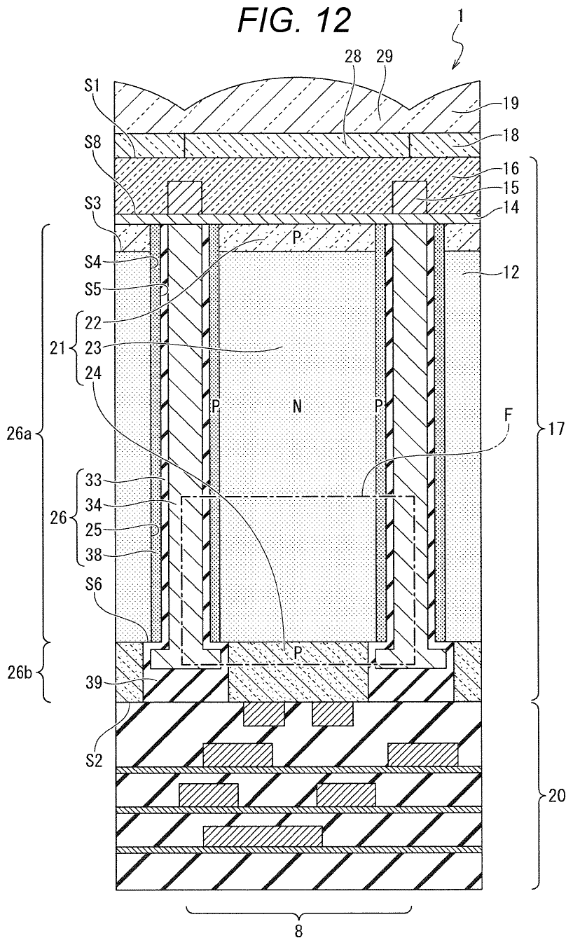

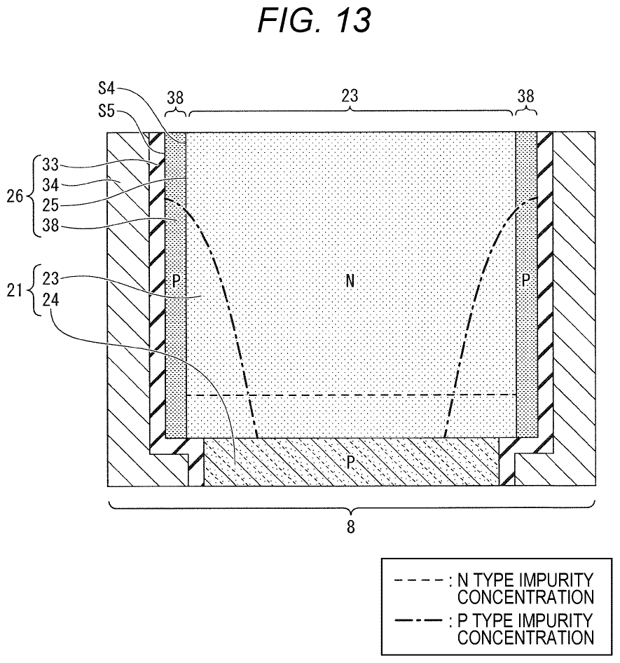

Next, a solid-state imaging device 1 according to a third embodiment of the present disclosure will be described. An overall configuration of the solid-state imaging device 1 according to the third embodiment is similar to that in FIG. 1, and thus illustration thereof will be omitted. FIG. 12 is a diagram illustrating a cross-sectional configuration of the solid-state imaging device 1 according to the third embodiment. Furthermore, FIG. 13 is a diagram illustrating a cross-sectional configuration of the solid-state imaging device 1 in a case where the region F in FIG. 12 is enlarged. In FIGS. 12 and 13, portions corresponding to those in FIGS. 8 and 9 are denoted by the same reference numerals, and redundant description is omitted.

As shown in FIGS. 12 and 13, the third embodiment is different from the second embodiment in that a P type solid-phase diffusion layer 38 is used instead of the semiconductor layer 27 shown in FIG. 8.

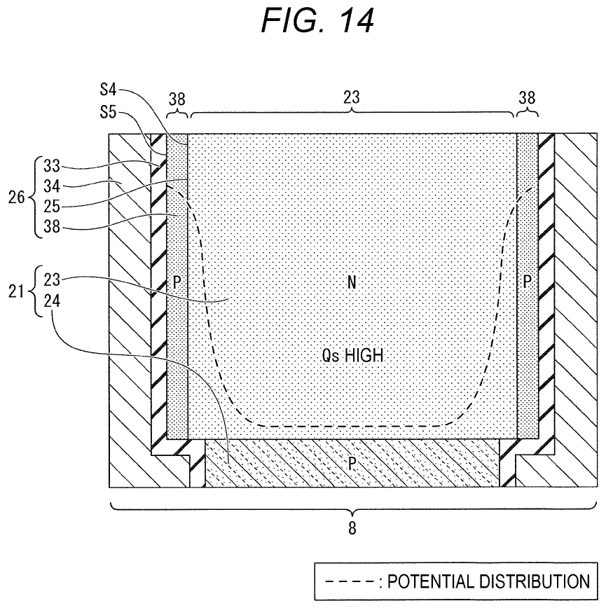

The P type solid-phase diffusion layer 38 is a layer disposed in the trench portion 25 and covering the side wall surface S4 of the trench portion 25. As the P type solid-phase diffusion layer 38, for example, a semiconductor layer obtained by introducing P type impurities (for example, boron (B)) into a non-doped epitaxial growth layer by solid-phase diffusion can be adopted. By using such a semiconductor layer, as shown in FIG. 13, the N type impurity concentration of the P type solid-phase diffusion layer 38 is 1e16/cm³ or less (low numerical value). By lowering the N type impurity concentration, as illustrated in FIG. 14, the P type solid-phase diffusion layer 38 can make the potential gradient due to the PN junction between the P type solid-phase diffusion layer 38 and the N type semiconductor region 23 steeper. Therefore, the saturation charge amount Qs of the photoelectric conversion unit 21 can be improved. In FIG. 13, a curve indicating an N type impurity concentration is indicated by a broken line, and a curve indicating a P type impurity concentration is indicated by a one-dot chain line in superposition with the N type semiconductor region 23 and the P type solid-phase diffusion layer 38. FIG. 14 is a diagram illustrating a potential distribution. In addition, in FIG. 14, a curve indicating a potential distribution is indicated by a broken line in superposition with the N type semiconductor region 23 and the P type solid-phase diffusion layer 38. Note that the distribution of the N type and P type impurity concentrations illustrated in FIG. 13 can be acquired, for example, by performing analysis by Nano-SIMS.

In addition, the photoelectric conversion unit 21 has the N type semiconductor region 23 in a region in contact with the P type solid-phase diffusion layer 38. As the N type semiconductor region 23, for example, a semiconductor region obtained by ion-implanting N type impurities from the front surface S2 side of the semiconductor substrate 12 is used. As a result, as illustrated in FIG. 13, the N type impurity concentration of the N type semiconductor region 23 is constant at each depth from the surface S2. Note that FIG. 12 illustrates a case where the fixed charge film 13 illustrated in FIG. 8 is omitted.

Further, the solid-state imaging device 1 includes a portion (hereinafter, also referred to as a “first element isolation portion 26a”) on the back surface S3 side of the element isolation portion 26 and a portion (hereinafter, also referred to as a “second element isolation portion 26b”) on the front surface S2 side of the element isolation portion 26. The width of the second element isolation portion 26b is formed to be wider than the width of the first element isolation portion 26a. In addition, an insulating material 39 is embedded in the second element isolation portion 26b.

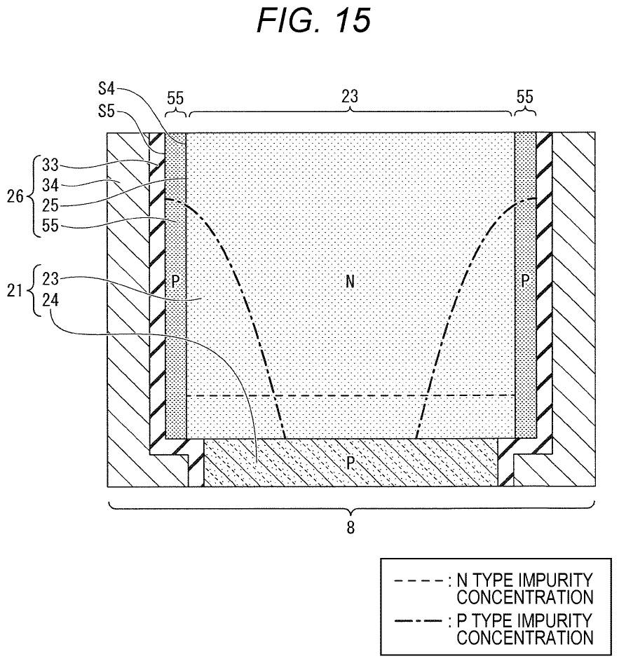

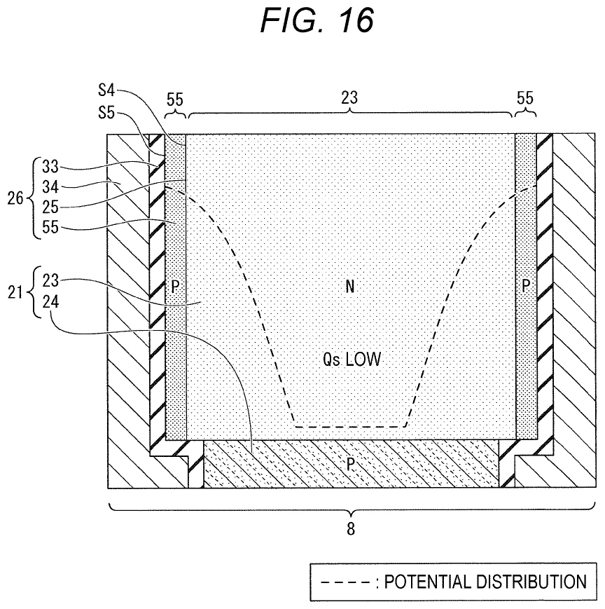

Here, for example, as illustrated in FIG. 15, in a case where a P type semiconductor region 55 obtained by ion-implanting P type impurities into the N type semiconductor region 23 from the side wall surface S4 of the trench portion 25 is used instead of the P type solid-phase diffusion layer 38, the N type impurities are mixed in the P type semiconductor region 55, and as illustrated in FIG. 16, a potential gradient due to the PN junction between the P type semiconductor region 55 and the N type semiconductor region 23 becomes gentle. Therefore, there is a possibility that the saturation charge amount Qs of the photoelectric conversion unit 21 decreases. In FIG. 15, a curve indicating an N type impurity concentration is indicated by a broken line, and a curve indicating a P type impurity concentration is indicated by a one-dot chain line in superposition with the N type semiconductor region 23 and the P type semiconductor region 55. FIG. 16 is a diagram illustrating a potential distribution. In addition, in FIG. 16, a curve indicating a potential distribution is indicated by a broken line in superposition with the N type semiconductor region 23 and the P type semiconductor region 55.

On the other hand, in the solid-state imaging device 1 according to the first embodiment, as illustrated in FIG. 13, the P type solid-phase diffusion layer 38 has an N type impurity concentration of 1e16/cm³ or less. Therefore, it is possible to prevent N type impurities from being mixed in the P type solid-phase diffusion layer 38, a potential gradient due to the PN junction between the P type solid-phase diffusion layer 38 and the N type semiconductor region 23 can be made steeper, and the saturation charge amount Qs of the photoelectric conversion unit 21 can be improved. Furthermore, even in a case where the pixels 8 are miniaturized, the necessary saturation charge amount Qs can be secured, and the solid-state imaging device 1 can be made to have multiple pixels relatively easily.

### 3-2 Method for Manufacturing Solid-State Imaging Device

Next, a method for manufacturing the solid-state imaging device 1 according to the third embodiment will be described.

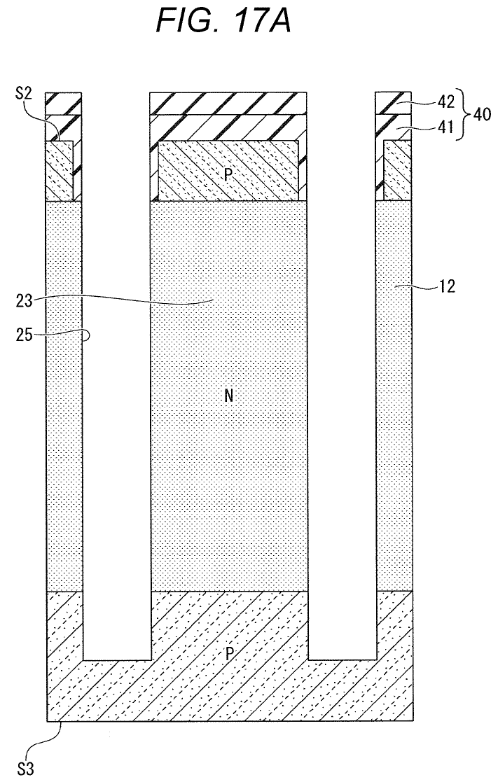

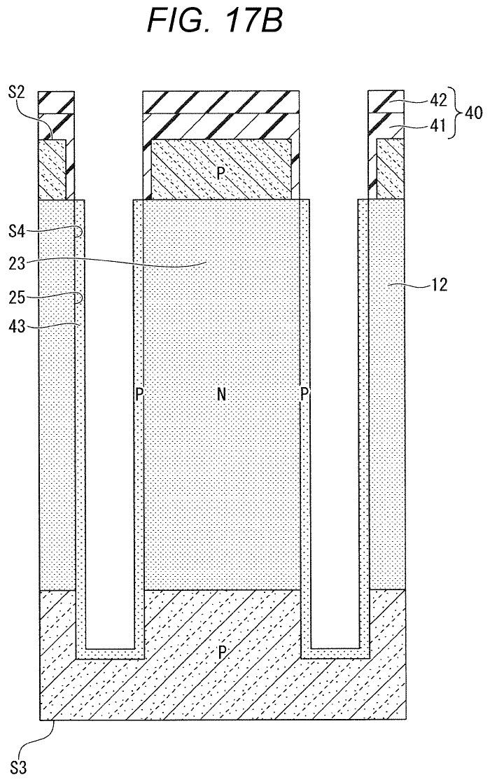

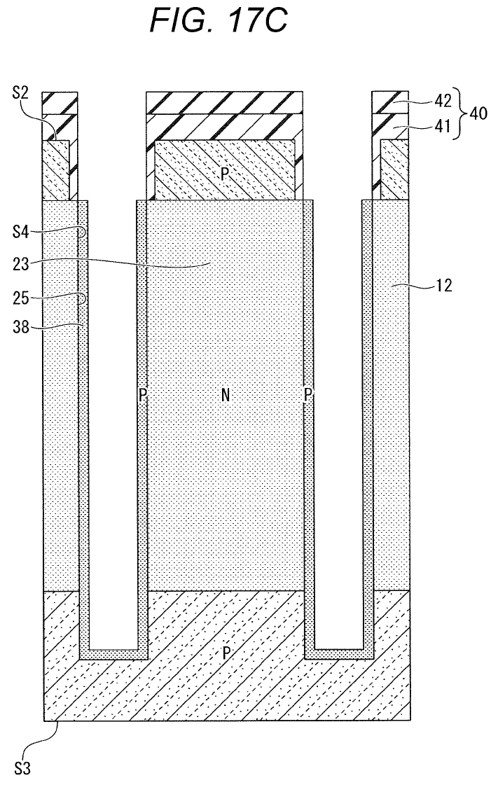

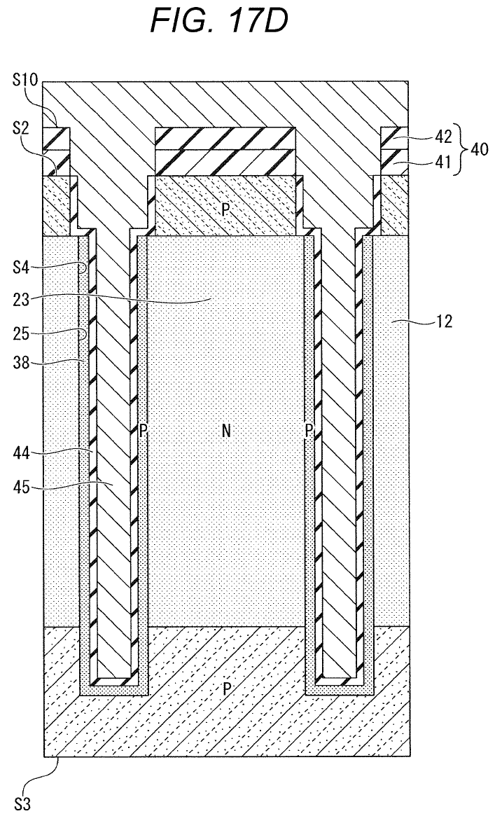

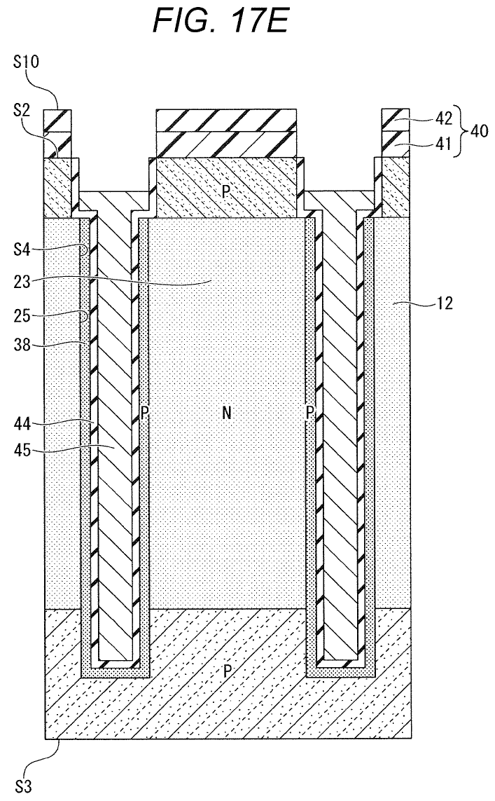

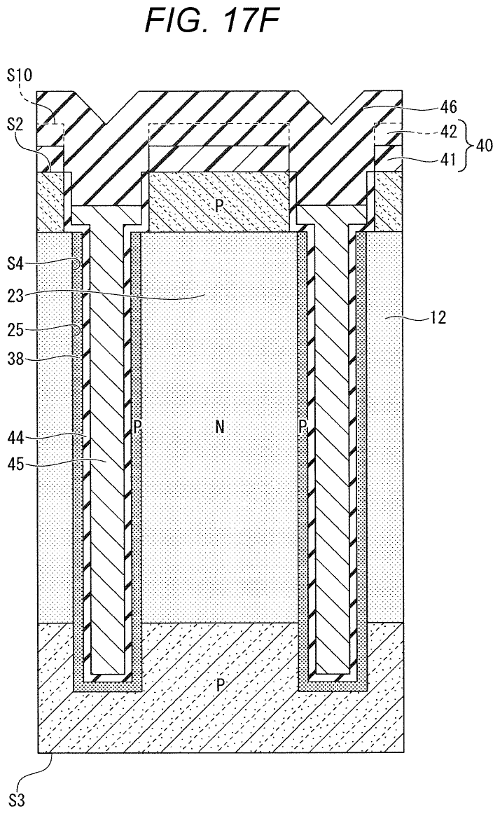

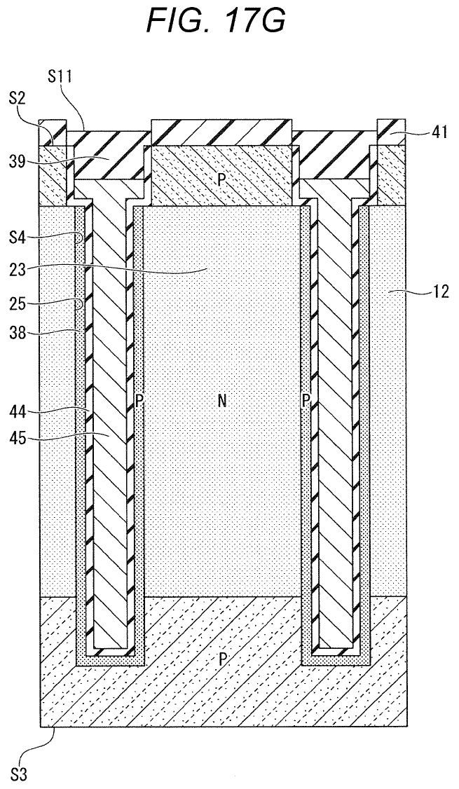

First, as illustrated in FIG. 17A, the P type semiconductor substrate 12 is prepared, and N type impurities (for example, phosphorus (P) and arsenic (As)) are ion-implanted from the surface S2 side of the prepared semiconductor substrate 12 to form the N type semiconductor region 23. The N type semiconductor region 23 has a constant N type impurity concentration at each depth from the surface S2. Subsequently, a mask 40 having an opening at a position where the trench portion 25 is to be formed is formed on the front surface S2 of the semiconductor substrate 12. The mask 40 is formed by laminating a silicon nitride (SiN) film 41 and a silicon oxide (SiO) film 42. Subsequently, anisotropic dry etching is performed through the mask 40 to form the trench portions 25.

Subsequently, as illustrated in FIG. 17B, a semiconductor crystal (silicon (Si)) is epitaxially grown on the side wall surface S4 of the trench portion 25, and the semiconductor layer 43 is formed in the trench portion 25 so as to cover the side wall surface S4 and the bottom surface of the trench portion 25. The semiconductor layer 43 is formed only at a position where the front surface S2 side of the trench portion 25 is covered with the silicon nitride film 41 and the first element isolation portion 26a (see FIG. 12) is formed. As the semiconductor layer 43, a non-doped epitaxial growth layer having an impurity concentration of 1e16/cm³ or less is formed. Subsequently, as illustrated in FIG. 17C, the semiconductor layer 43 is doped with P type impurities (for example, boron (B)) from the inside of the trench portion 25 by a solid-phase diffusion method to form the P type solid-phase diffusion layer 38. That is, the semiconductor layer 43 is changed to the P type solid-phase diffusion layer 38. As a result, it is possible to prevent the N type impurities from being mixed in the P type solid-phase diffusion layer 38, and the concentration of the N type impurities in the P type solid-phase diffusion layer 38 can be set to 1e16/cm³ or less.

Subsequently, as illustrated in FIG. 17D, silicon oxide (SiO) 44 and doped polysilicon 45 are embedded in this order in the space inside the trench portion 25 covered with the P type solid-phase diffusion layer 38. The silicon oxide 44 is embedded so as to cover the side surface of the P type solid-phase diffusion layer 38. The doped polysilicon 45 is embedded until the doped polysilicon 45 covers the entire surface S10 of the mask 40. Subsequently, as illustrated in FIG. 17E, etch-back is performed to remove the doped polysilicon 45 from the front surface S10 of the mask 40 and the position at which the insulating material 39 (see FIG. 12) in the trench portion 25 is embedded. Subsequently, as illustrated in FIG. 17F, the insulating material 46 is embedded on the front surface S2 side of the trench portion 25. The embedding of the insulating material 46 is performed until the insulating material 46 covers the entire surface S10 of the mask 40. Subsequently, as illustrated in FIG. 17G, the insulating material 46 is polished from the surface S11 side by using a CMP technique to form the insulating material 39. By such a procedure, the element isolation portion 26 illustrated in FIG. 12 is formed. Subsequently, as illustrated in FIG. 12, the insulating film 14, the light shielding film 15, the planarizing film 16, the color filter layer 18, and the microlens array 19 are formed. As a result, the solid-state imaging device 1 illustrated in FIG. 12 is manufactured.

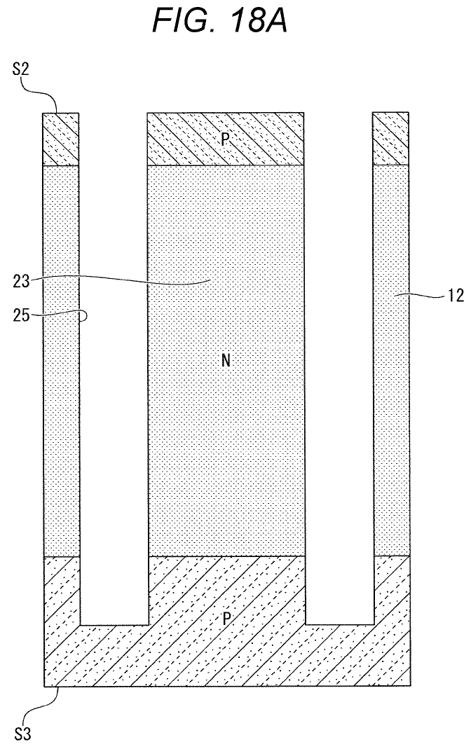

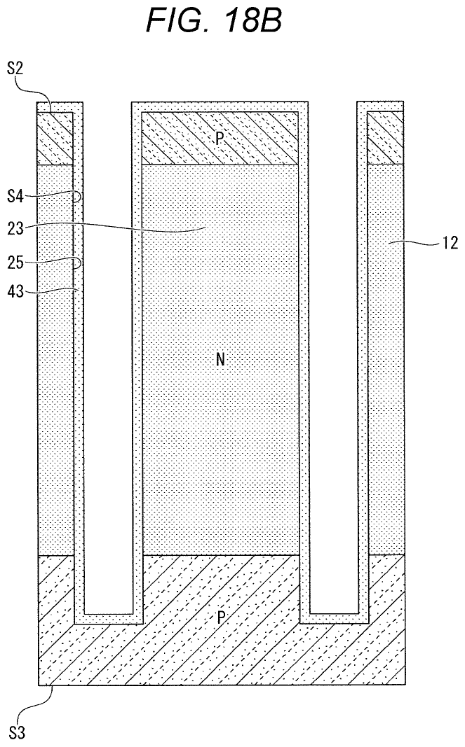

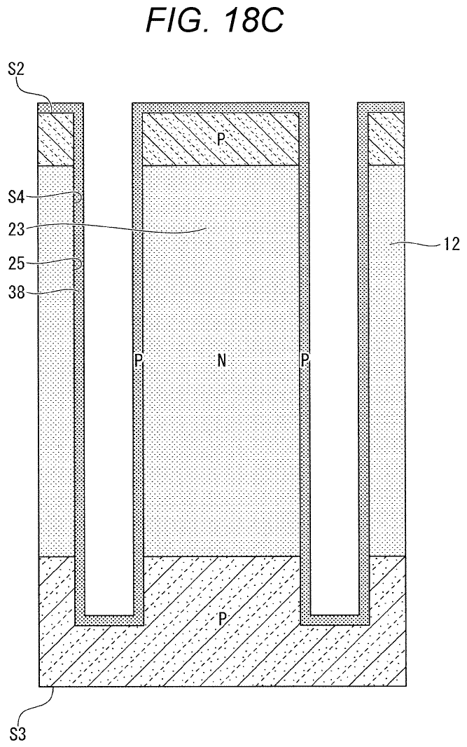

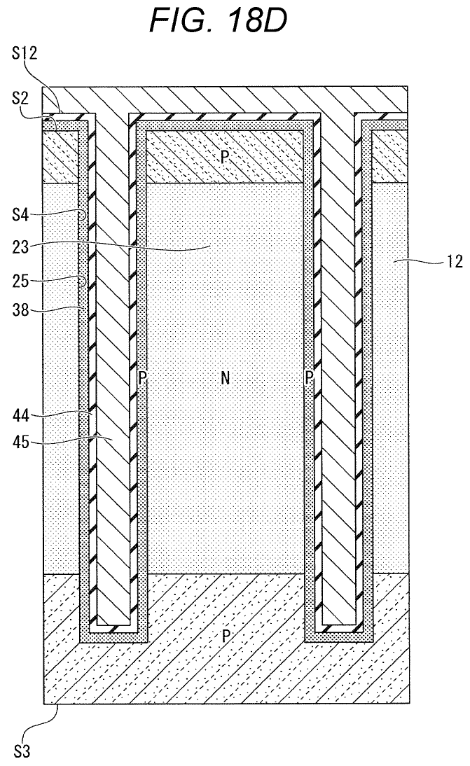

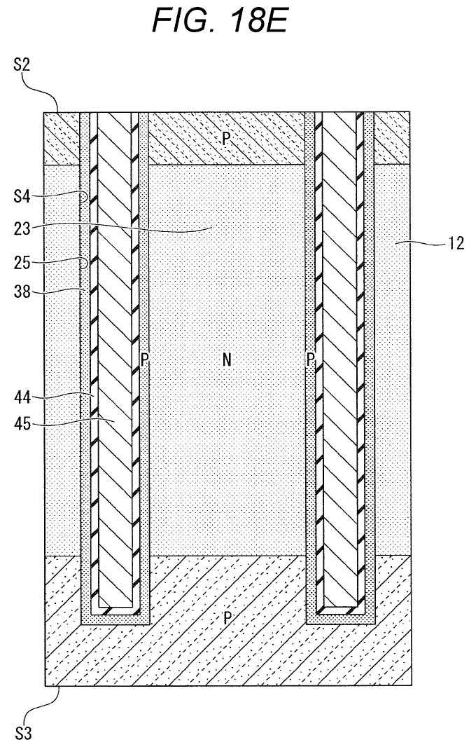

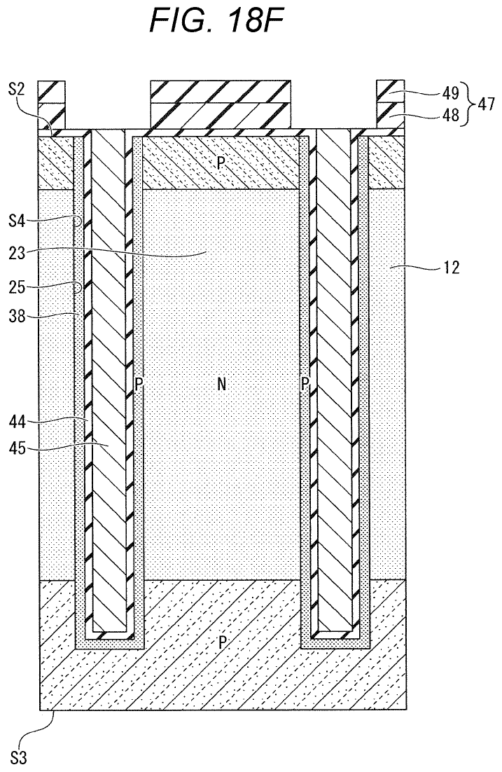

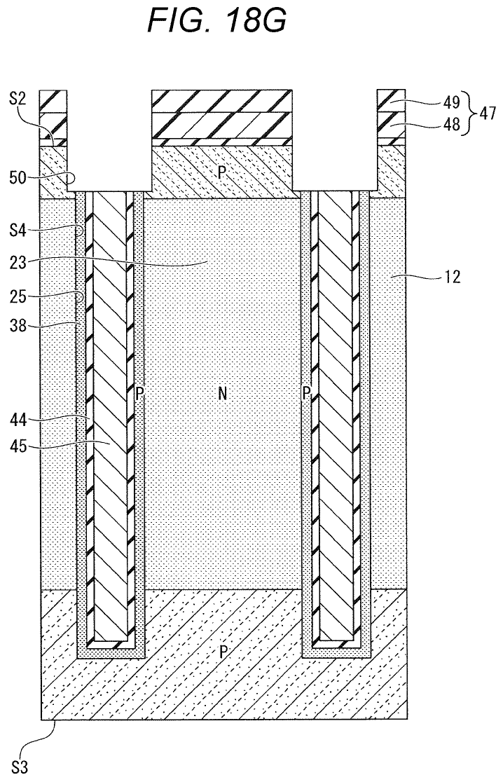

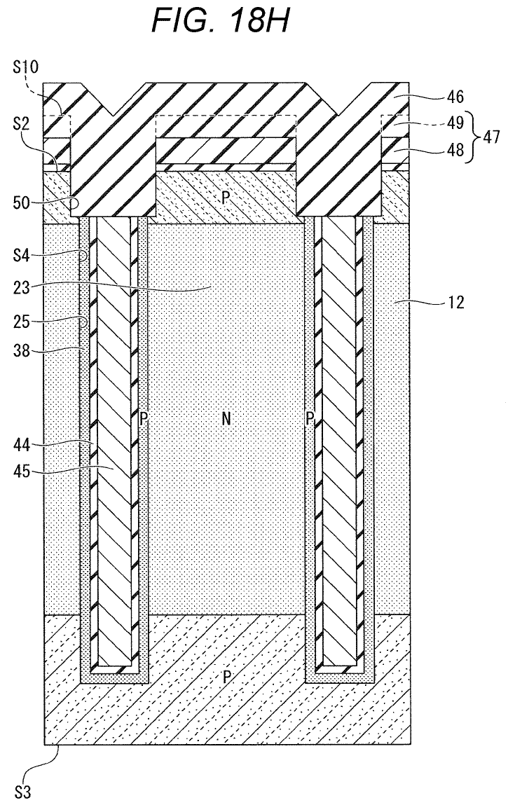

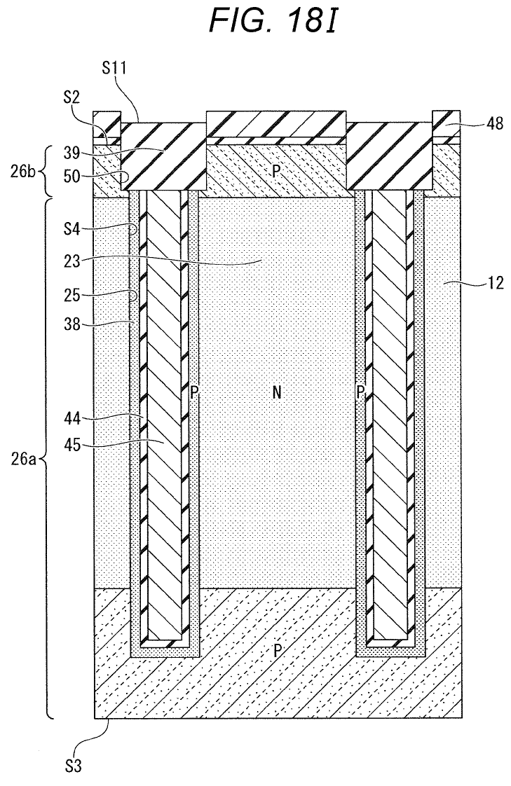

Next, another method for manufacturing the solid-state imaging device 1 will be described. Note that, as illustrated in FIG. 18I, the configuration of the second element isolation portion 26b formed by this manufacturing method is slightly different from the configuration of the second element isolation portion 26b formed by the above forming method.

First, as illustrated in FIG. 18A, N type impurities are ion-implanted into the P type semiconductor substrate 12 to form the N type semiconductor region 23, similarly to the above forming method. Subsequently, etching is performed from the front surface S2 side of the semiconductor substrate 12 through a mask (not illustrated) to form the trench portions 25. Subsequently, as illustrated in FIG. 18B, a semiconductor crystal is epitaxially grown on the side wall surface S4 and the like of the trench portion 25, and the semiconductor layer 43 is formed in the trench portion 25 and on the front surface S2 of the semiconductor substrate 12 so as to continuously cover the entire side wall surface S4 and the bottom surface of the trench portion 25 and the front surface S2 of the semiconductor substrate 12. As the semiconductor layer 43, a non-doped epitaxial growth layer having an impurity concentration of 1e16/cm³ or less is formed. Subsequently, as illustrated in FIG. 18C, the semiconductor layer 43 is doped with P type impurities (for example, boron (B)) from the inside of the trench portion 25 or the like by a solid-phase diffusion method to form the P type solid-phase diffusion layer 38. That is, the semiconductor layer 43 is changed to the P type solid-phase diffusion layer 38. As a result, it is possible to prevent the N type impurities from being mixed in the P type solid-phase diffusion layer 38, and the concentration of the N type impurities in the P type solid-phase diffusion layer 38 can be set to 1e16/cm³ or less.

Subsequently, as illustrated in FIG. 18D, the silicon oxide (SiO) 44 and the doped polysilicon 45 are embedded in this order in the space inside the trench portion 25 covered with the P type solid-phase diffusion layer 38. The silicon oxide 44 is embedded so as to cover the side surface of the P type solid-phase diffusion layer 38. In addition, the doped polysilicon 45 is embedded until the doped polysilicon 45 covers the entire surface S12 of the silicon oxide 44. Subsequently, as illustrated in FIG. 18E, polishing or the like is performed from the front surface S2 side of the semiconductor substrate 12 using a CMP technique or etch back to expose the front surface S2 of the semiconductor substrate 12. Subsequently, as illustrated in FIG. 18F, a mask 47 having an opening at a position where the second element isolation portion 26b (see FIG. 12) is to be formed is formed on the front surface S2 of the semiconductor substrate 12. The mask 47 is formed by laminating a silicon nitride (SiN) film 48 and a silicon oxide (SiO) film 49. Subsequently, as illustrated in FIG. 18G, etching is performed via the mask 47 to form a portion (hereinafter, also referred to as a “trench portion 50”) of the trench portion 25 where the second element isolation portion 26b (see FIG. 12) is to be formed. Subsequently, as illustrated in FIG. 18H, the insulating material 46 is embedded in the trench portion 50. The embedding of the insulating material 46 is performed until the insulating material 46 covers the entire surface S10 of the mask 47. Subsequently, as illustrated in FIG. 18I, the insulating material 46 is polished from the surface S11 side by using a CMP technique to form the insulating material 39 illustrated in FIG. 12. By such a procedure, the element isolation portion 26 illustrated in FIG. 12 is formed. Subsequently, as illustrated in FIG. 12, the insulating film 14, the light shielding film 15, the planarizing film 16, the color filter layer 18, and the microlens array 19 are formed. As a result, the solid-state imaging device 1 illustrated in FIG. 12 is manufactured.

### 3-3 Modification

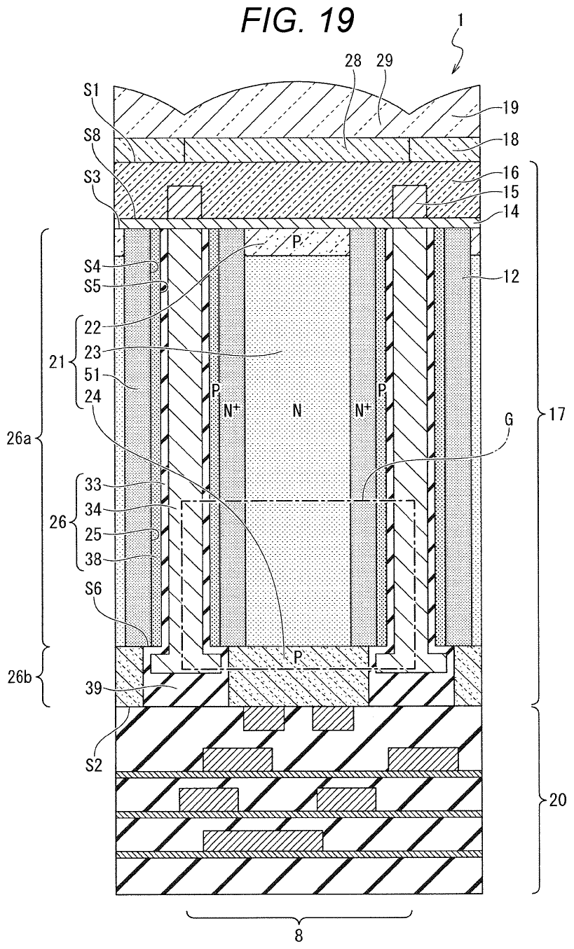

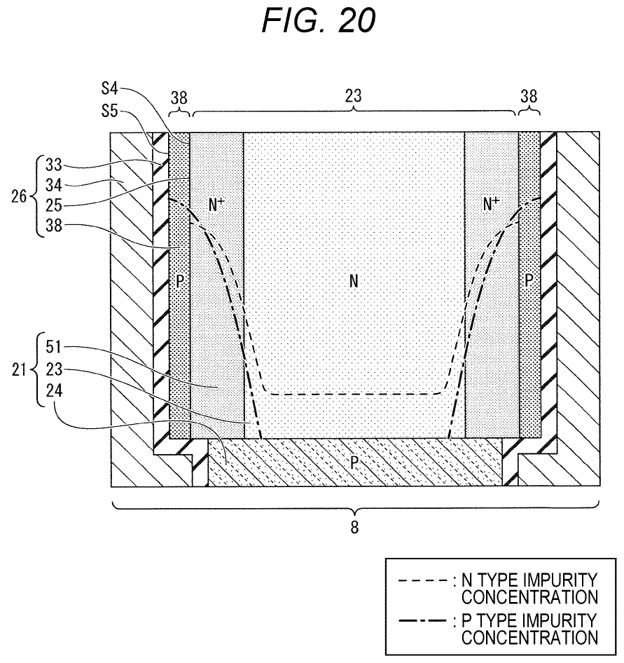

(1) Note that, in the third embodiment, an example has been described in which the N type semiconductor region 23 is provided as the N type region of the photoelectric conversion unit 21, but other configurations can be adopted. For example, as illustrated in FIGS. 19 and 20, an N type semiconductor region (hereinafter, also referred to as an “N+ type semiconductor region 51”) having a relatively high N type impurity concentration may be provided as a part of the N type semiconductor region 23 in a region of the photoelectric conversion unit 21 in contact with the trench portion 25. As a result, since a PN junction is formed between the P type solid-phase diffusion layer 38 and the N+ type semiconductor region 51 (region having a relatively high N type impurity concentration), the potential gradient can be made steeper, and the saturation charge amount Qs of the photoelectric conversion unit 21 can be increased. In FIG. 20, a curve indicating an N type impurity concentration is indicated by a broken line, and a curve indicating a P type impurity concentration is indicated by a one-dot chain line in superposition with the N type semiconductor region 23 and the P type solid-phase diffusion layer 38.

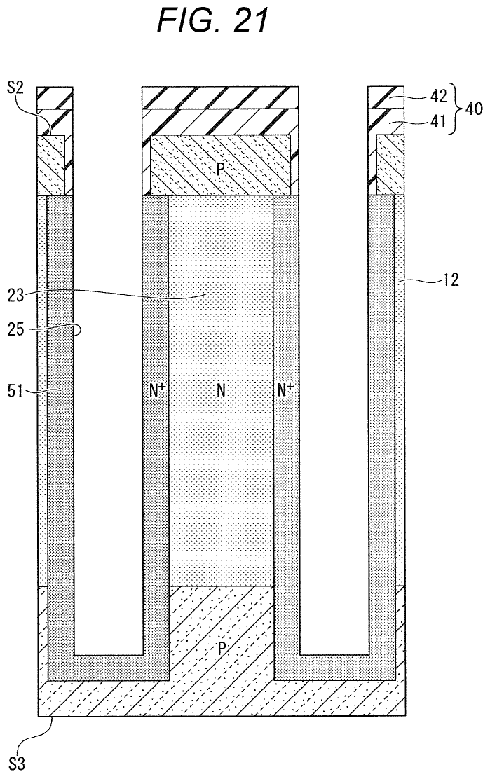

A method for forming the element isolation portion 26 when such a configuration is adopted will be described. In the case of adopting a forming method similar to the manufacturing method illustrated in FIGS. 17A to 17G, first, N type impurities are ion-implanted into the P type semiconductor substrate 12 to form the N type semiconductor region 23, similarly to the step illustrated in FIG. 17A. Subsequently, etching is performed from the front surface S2 side of the semiconductor substrate 12 through the mask 40 to form the trench portions 25. Subsequently, as illustrated in FIG. 21, N type impurities are ion-implanted from the inside of the trench portion 25 to form the N+ type semiconductor region 51 on the side wall surface S4 and the bottom surface of the trench portion 25. Subsequently, similarly to the step illustrated in FIG. 17B, a semiconductor crystal is epitaxially grown on the side wall surface S4 of the trench portion 25, and the semiconductor layer 43 is formed in the trench portion 25 so as to cover the side wall surface S4 and the bottom surface of the trench portion 25. Thereafter, the element isolation portion 26 illustrated in FIG. 19 is formed through the steps illustrated in FIGS. 17C to 17G.

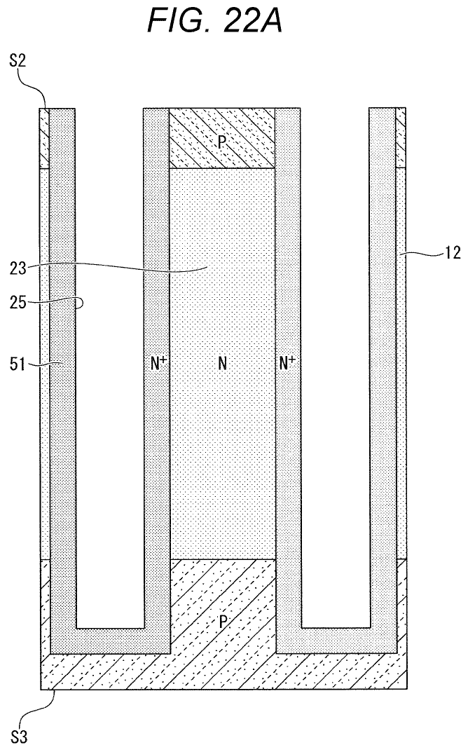

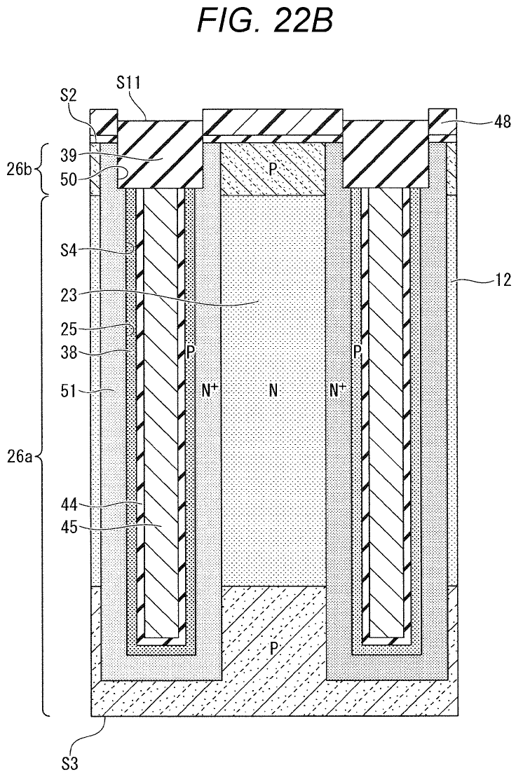

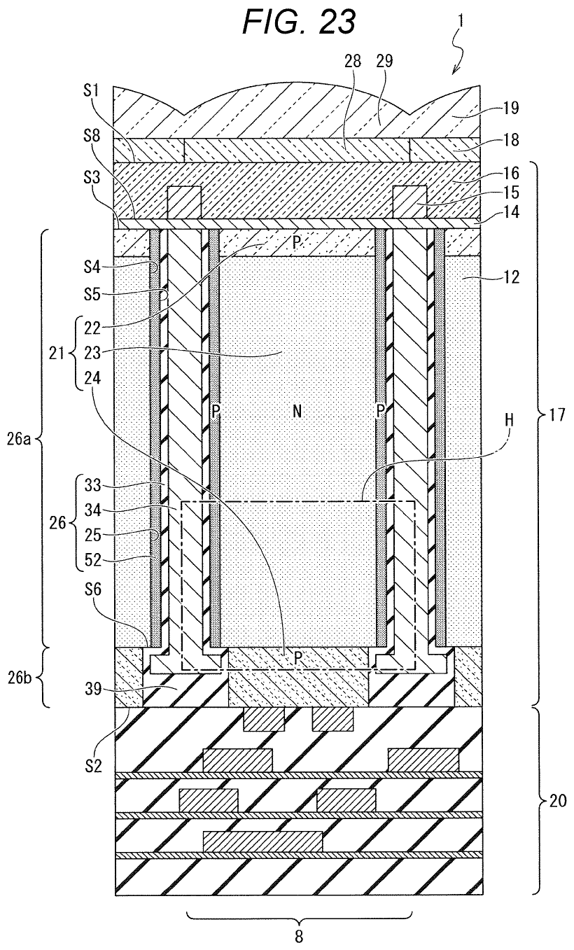

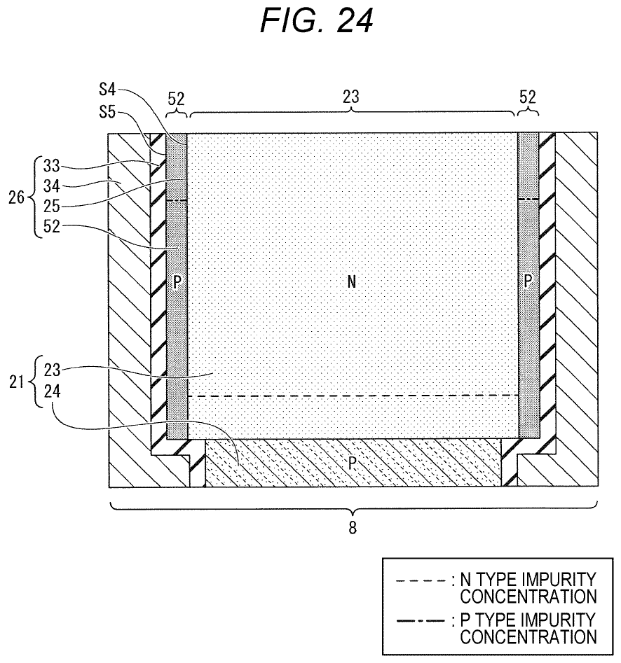

In addition, in a case of adopting a forming method similar to the method for forming the element isolation portion 26 illustrated in FIGS. 18A to 18I, first, N type impurities are ion-implanted into the P type semiconductor substrate 12 to form the N type semiconductor region 23, similarly to the step illustrated in FIG. 18A. Subsequently, etching is performed from the front surface S2 side of the semiconductor substrate 12 through a mask (not illustrated) to form the trench portions 25. Subsequently, as illustrated in FIG. 22A, N type impurities are ion-implanted from the inside of the trench portion 25 to form the N+ type semiconductor region 51 on the entire side wall surface S4 and the bottom surface of the trench portion 25. Subsequently, similarly to the step illustrated in FIG. 18B, a semiconductor crystal is epitaxially grown on the side wall surface S4 of the trench portion 25, and the semiconductor layer 43 is formed in the trench portion 25 and on the front surface S2 of the semiconductor substrate 12 so as to continuously cover the entire side wall surface S4 and the bottom surface of the trench portion 25 and the front surface S2 of the semiconductor substrate 12. Thereafter, the element isolation portion 26 illustrated in FIG. 22B is formed through the steps illustrated in FIGS. 18C to 18I. Note that, as illustrated in FIG. 22B, the configuration of the second element isolation portion 26b formed by this forming method is slightly different from the configuration of the second element isolation portion 26b formed by the above forming method (the configuration of the second element isolation portion 26b in FIG. 19).
(2) Furthermore, in the third embodiment, an example has been described in which the P type solid-phase diffusion layer 38 is provided as the P type layer of the element isolation portion 26, but other configurations can also be adopted. For example, as illustrated in FIGS. 23 and 24, instead of the P type solid-phase diffusion layer 38, a P type epitaxial growth layer 52 formed by epitaxial growth while adding P type impurities may be provided. Here, for example, when a layer formed by ion-implanting P type impurities from the inside of the trench portion 25 is used instead of the P type epitaxial growth layer 52, the P type impurities may be ion-implanted into the N type semiconductor region 23 at the time of forming this layer. On the other hand, when the P type epitaxial growth layer 52 is used, P type impurities do not need to be mixed into the N type semiconductor region 23 as illustrated in FIG. 24 at the time of forming the P type epitaxial growth layer 52. Therefore, since the PN junction is formed by the N type semiconductor region 23 having a low P type impurity concentration and the P type epitaxial growth layer 52, the potential gradient can be made steeper, and the saturation charge amount Qs of the photoelectric conversion unit 21 can be increased. In FIG. 24, a curve indicating an N type impurity concentration is indicated by a broken line, and a curve indicating a P type impurity concentration is indicated by a one-dot chain line in superposition with the N type semiconductor region 23 and the P type solid-phase diffusion layer 38.

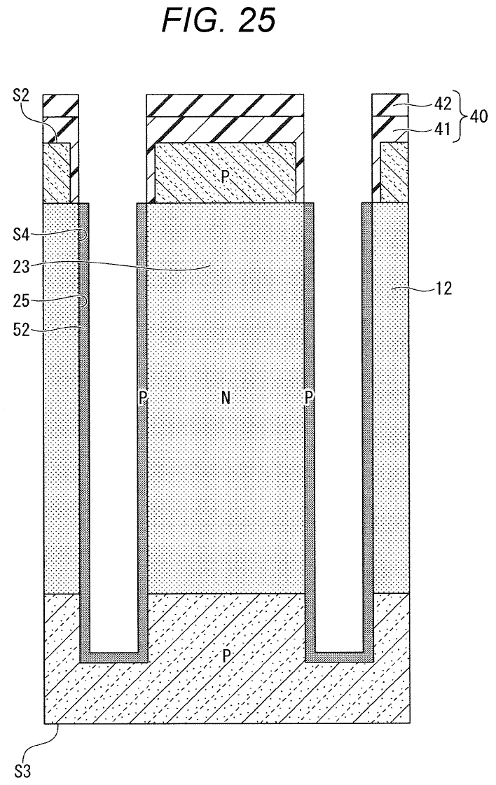

A method for forming the element isolation portion 26 in a case where such a configuration is adopted will be described. In the case of adopting a forming method similar to the manufacturing method illustrated in FIGS. 17A to 17G, first, N type impurities are ion-implanted into the P type semiconductor substrate 12 to form the N type semiconductor region 23, similarly to the step illustrated in FIG. 17A. Subsequently, etching is performed from the front surface S2 side of the semiconductor substrate 12 through the mask 40 to form the trench portions 25. Subsequently, as illustrated in FIG. 25, a semiconductor crystal is epitaxially grown on the side wall surface S4 of the trench portion 25 while adding P type impurities, and the P type epitaxial growth layer 52 is formed in the trench portion 25 so as to cover the side wall surface S4 and the bottom surface of the trench portion 25. Thereafter, the step illustrated in FIG. 17C is omitted, and the element isolation portion 26 illustrated in FIG. 23 is formed through the steps illustrated in FIGS. 17D to 17G.

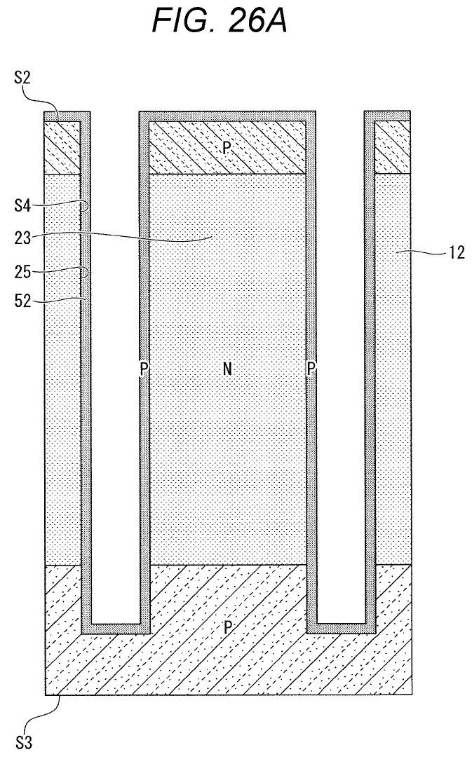

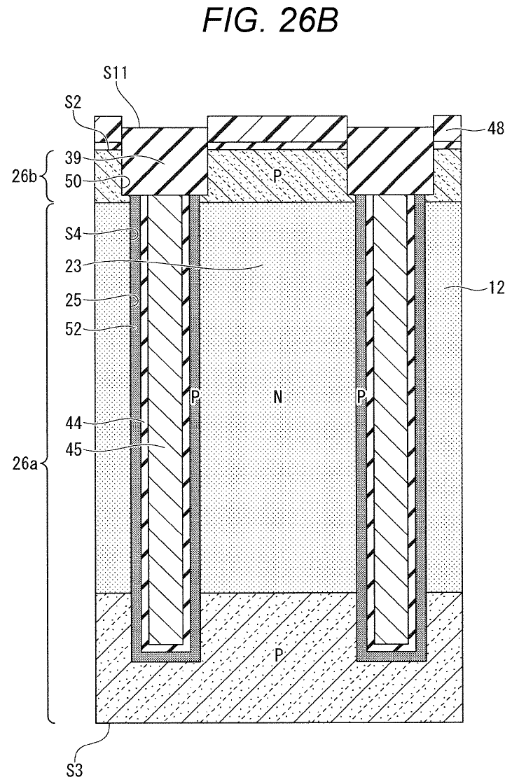

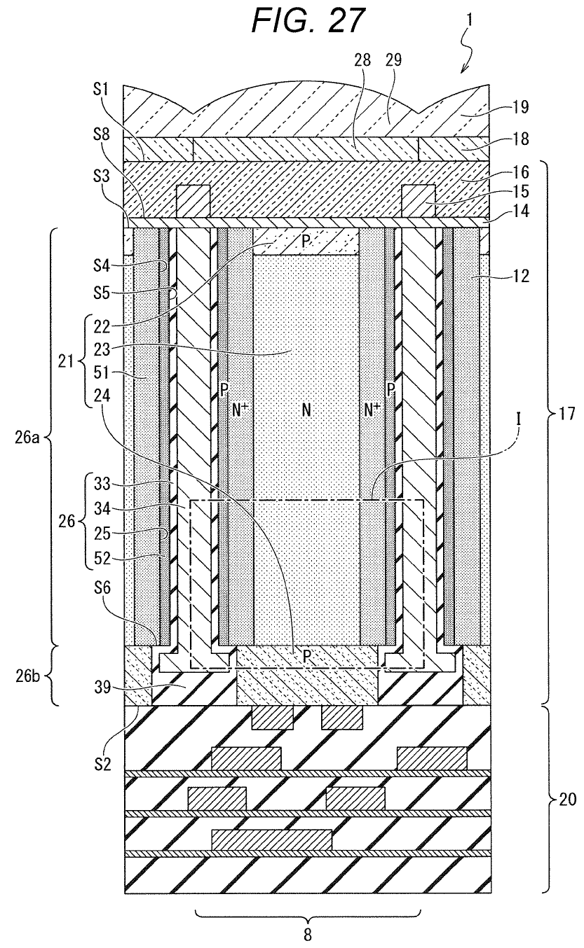

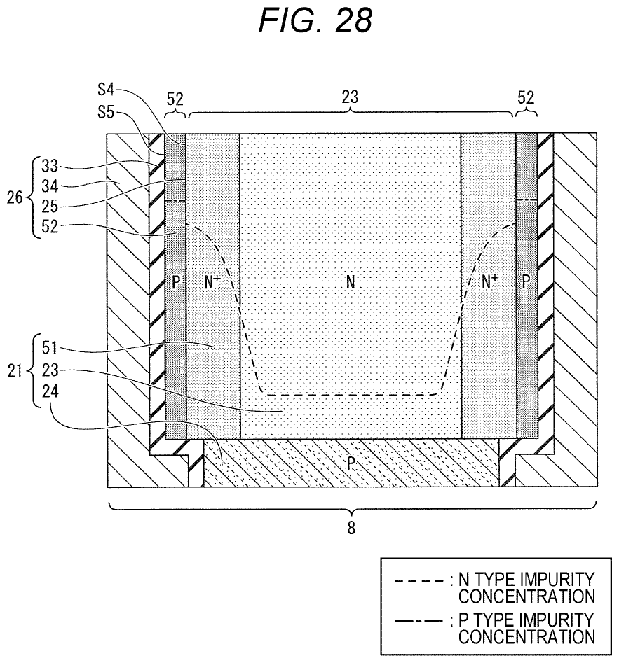

In addition, in a case of adopting a forming method similar to the method for forming the element isolation portion 26 illustrated in FIGS. 18A to 18I, first, N type impurities are ion-implanted into the P type semiconductor substrate 12 to form the N type semiconductor region 23, similarly to the step illustrated in FIG. 18A. Subsequently, etching is performed from the front surface S2 side of the semiconductor substrate 12 through a mask (not illustrated) to form the trench portions 25. Subsequently, as illustrated in FIG. 26A, a semiconductor crystal is epitaxially grown while adding P type impurities to the side wall surface S4 or the like of the trench portion 25, and the P type epitaxial growth layer 52 is formed in the trench portion 25 and on the front surface S2 of the semiconductor substrate 12 so as to continuously cover the entire side wall surface S4 and the bottom surface of the trench portion 25 and the front surface S2 of the semiconductor substrate 12. Thereafter, the step illustrated in FIG. 18C is omitted, and the steps illustrated in FIGS. 18D to 18I are performed to form the element isolation portion 26 illustrated in FIG. 26B. Note that, as illustrated in FIG. 26B, the configuration of the second element isolation portion 26b formed by this forming method is slightly different from the configuration of the second element isolation portion 26b formed by the above forming method (the configuration of the second element isolation portion 26b in FIG. 23).
(3) In addition, for example, as illustrated in FIGS. 27 and 28, the N+ type semiconductor region 51 illustrated in FIG. 19 and the P type epitaxial growth layer 52 illustrated in FIG. 23 may be provided by combining the above-described modifications (1) and (2). As a result, the saturation charge amount Qs of the photoelectric conversion unit 21 can be increased. In FIG. 28, a curve indicating an N type impurity concentration is indicated by a broken line, and a curve indicating a P type impurity concentration is indicated by a one-dot chain line in superposition with the N type semiconductor region 23 and the P type solid-phase diffusion layer 38.

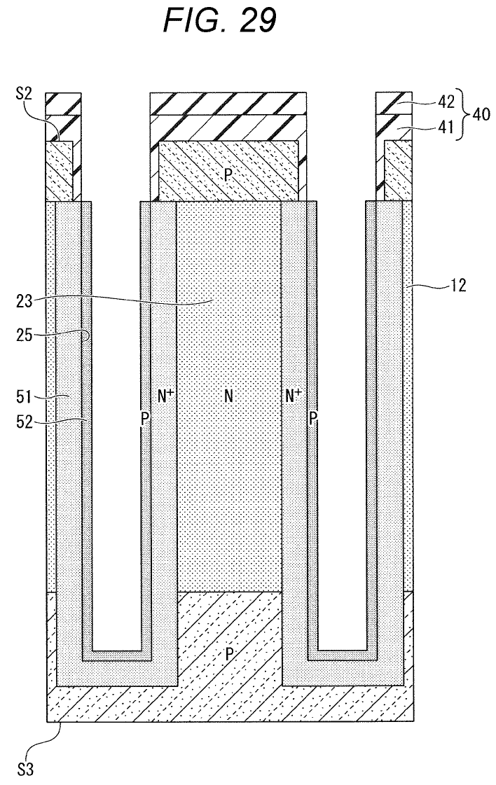

A method for forming the element isolation portion 26 in a case where such a configuration is adopted will be described. In the case of adopting a forming method similar to the manufacturing method illustrated in FIGS. 17A to 17G, first, N type impurities are ion-implanted into the P type semiconductor substrate 12 to form the N type semiconductor region 23, similarly to the step illustrated in FIG. 17A. Subsequently, etching is performed from the front surface S2 side of the semiconductor substrate 12 through the mask 40 to form the trench portions 25. Subsequently, similarly to the step illustrated in FIG. 21, N type impurities are ion-implanted from the inside of the trench portion 25 to form the N+ type semiconductor region 51 on the side wall surface S4 and the bottom surface of the trench portion 25. Subsequently, as illustrated in FIG. 29, a semiconductor crystal is epitaxially grown on the side wall surface S4 of the trench portion 25 while adding P type impurities, and the P type epitaxial growth layer 52 is formed in the trench portion 25 so as to cover the side wall surface S4 and the bottom surface of the trench portion 25. Thereafter, the step illustrated in FIG. 17C is omitted, and the element isolation portion 26 illustrated in FIG. 27 is formed through the steps illustrated in FIGS. 17D to 17G.

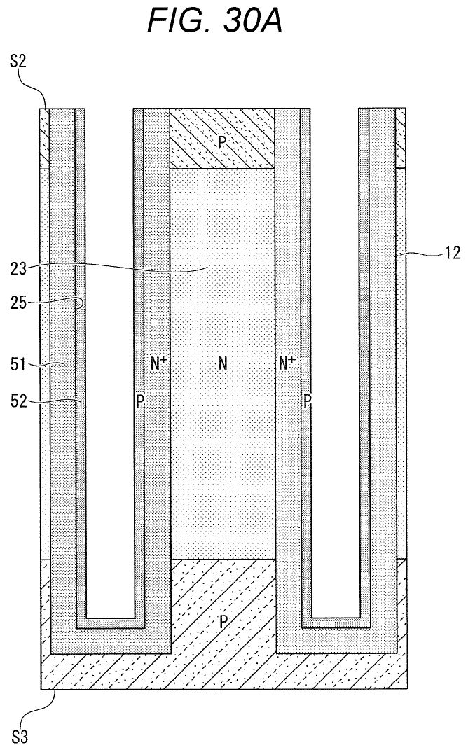

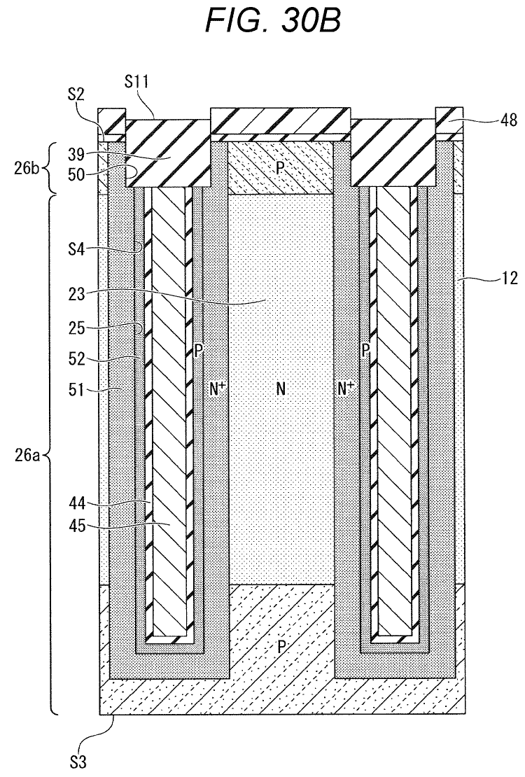

In addition, in a case of adopting a forming method similar to the method for forming the element isolation portion 26 illustrated in FIGS. 18A to 18I, first, N type impurities are ion-implanted into the P type semiconductor substrate 12 to form the N type semiconductor region 23, similarly to the step illustrated in FIG. 18A. Subsequently, etching is performed from the front surface S2 side of the semiconductor substrate 12 through a mask (not illustrated) to form the trench portions 25. Subsequently, similarly to the step illustrated in FIG. 22A, N type impurities are ion-implanted from the inside of the trench portion 25 to form the N+ type semiconductor region 51 on the entire side wall surface S4 and the bottom surface of the trench portion 25. Subsequently, as illustrated in FIG. 30A, a semiconductor crystal is epitaxially grown while adding P type impurities to the side wall surface S4 or the like of the trench portion 25, and the P type epitaxial growth layer 52 is formed in the trench portion 25 and on the front surface S2 of the semiconductor substrate 12 so as to continuously cover the entire side wall surface S4 and the bottom surface of the trench portion 25 and the front surface S2 of the semiconductor substrate 12. Thereafter, the step illustrated in FIG. 18C is omitted, and the steps illustrated in FIGS. 18D to 18I are performed to form the element isolation portion 26 illustrated in FIG. 30B. Note that, as illustrated in FIG. 30B, the configuration of the second element isolation portion 26b formed by this forming method is slightly different from the configuration of the second element isolation portion 26b formed by the above forming method (the configuration of the second element isolation portion 26b in FIG. 27).

### 4. FOURTH EMBODIMENT: SOLID-STATE IMAGING DEVICE

### 4-1 Configuration of Main Part

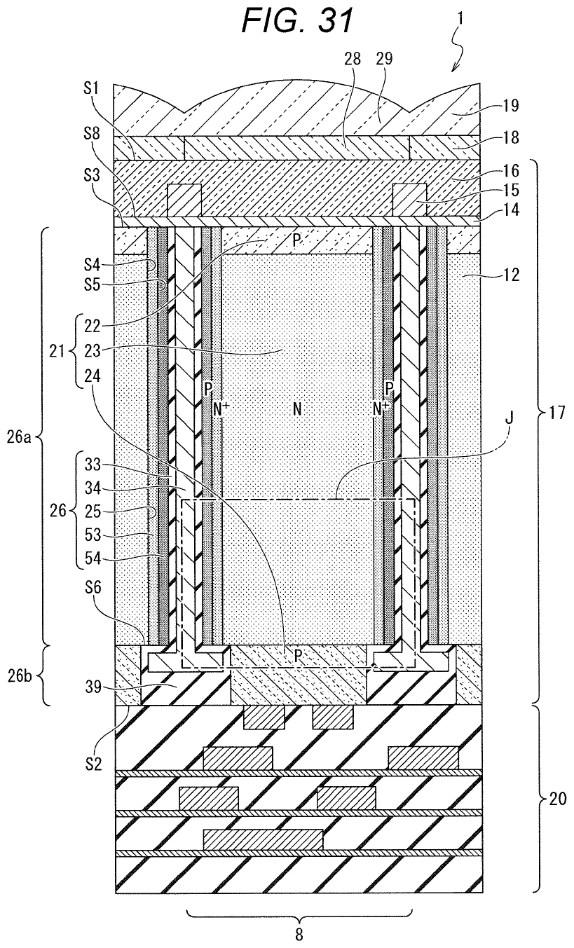

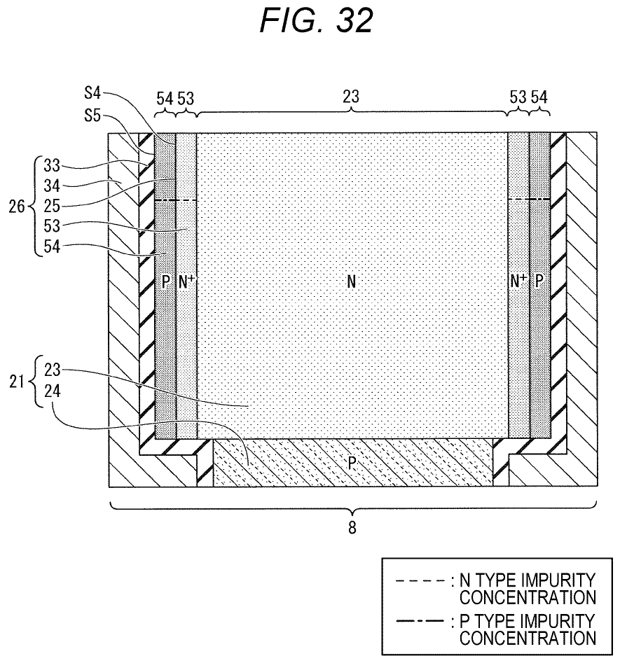

Next, a solid-state imaging device 1 according to a fourth embodiment of the present disclosure will be described. An overall configuration of the solid-state imaging device 1 according to the fourth embodiment is similar to that in FIG. 1, and thus illustration thereof will be omitted. FIG. 31 is a diagram illustrating a cross-sectional configuration of the solid-state imaging device 1 according to the fourth embodiment. Furthermore, FIG. 32 is a diagram illustrating a cross-sectional configuration of the solid-state imaging device 1 in a case where the region J in FIG. 31 is enlarged. In FIGS. 31 and 32, portions corresponding to those in FIGS. 12 and 13 are denoted by the same reference numerals, and redundant description is omitted.

As shown in FIGS. 31 and 32, the fourth embodiment is different from the third embodiment in that an N type epitaxial growth layer 53 and a P type epitaxial growth layer 54 are used instead of the P type solid-phase diffusion layer 38 shown in FIG. 12. The N type epitaxial growth layer 53 and the P type epitaxial growth layer 54 are laminated in this order on the side wall surface S4 of the trench portion 25.

The N type epitaxial growth layer 53 is a layer disposed in the trench portion 25 and covering the side wall surface S4 of the trench portion 25. As the N type epitaxial growth layer 53, for example, an epitaxial growth layer formed by epitaxial growth while adding N type impurities can be adopted. By using such an epitaxial growth layer, as illustrated in FIG. 31, the P type impurity concentration of the N type epitaxial growth layer 53 is 1e16/cm³ or less. By lowering the P type impurity concentration, the N type epitaxial growth layer 53 can make the potential gradient due to the PN junction between the N type epitaxial growth layer 53 and the P type epitaxial growth layer 54 steeper. Therefore, the saturation charge amount Qs of the photoelectric conversion unit 21 can be improved. In FIG. 31, a curve indicating an N type impurity concentration is indicated by a broken line, and a curve indicating a P type impurity concentration is indicated by a one-dot chain line in superposition with the N type semiconductor region 23, the N type epitaxial growth layer 53, and the P type epitaxial growth layer 54.

The P type epitaxial growth layer 54 is a layer disposed in the space inside the trench portion 25 covered with the N type epitaxial growth layer 53 and in contact with the N type epitaxial growth layer 53. As a result, the P type epitaxial growth layer 54 is laminated on the surface of the N type epitaxial growth layer 53 on the center side in the width direction of the trench portion 25, and forms a PN junction with the N type epitaxial growth layer 53. As the P type epitaxial growth layer 54, for example, an epitaxial growth layer formed by epitaxial growth while adding P type impurities can be adopted. By using such an epitaxial growth layer, as illustrated in FIG. 31, the N type impurity concentration of the P type epitaxial growth layer 54 is 1e16/cm³ or less. By lowering the N type impurity concentration, the P type epitaxial growth layer 54 can make the potential gradient due to the PN junction steeper. Therefore, it is possible to further suppress a decrease in the saturation charge amount Qs of the photoelectric conversion unit 21. Note that FIG. 12 illustrates a case where the fixed charge film 13 illustrated in FIG. 8 is omitted.

### 4-2 Method for Manufacturing Solid-State Imaging Device

Next, a method for manufacturing the solid-state imaging device 1 according to the fourth embodiment will be described.

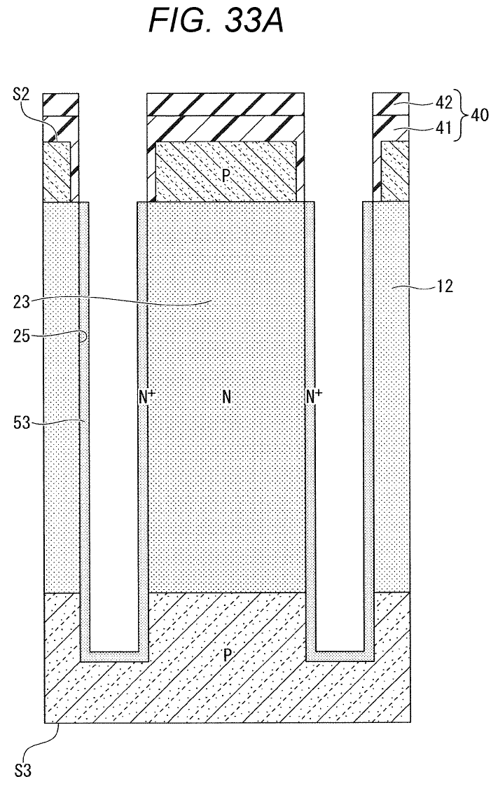

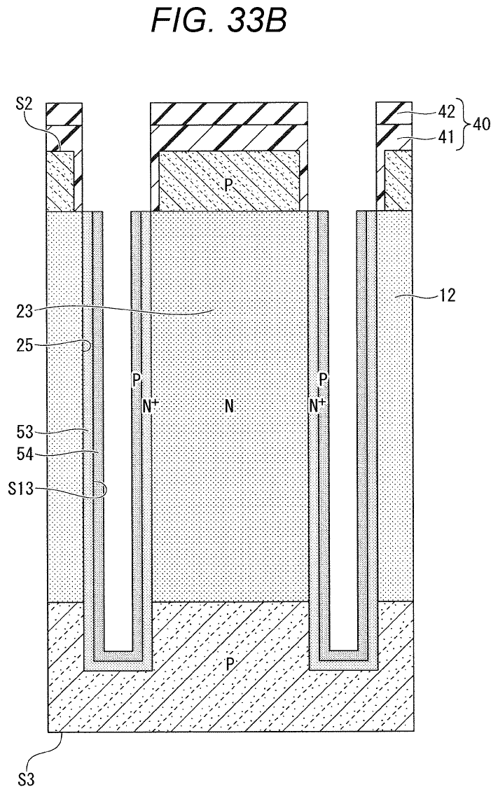

In a case of adopting a manufacturing method similar to the manufacturing method illustrated in FIGS. 17A to 17G, N type impurities are ion-implanted into the P type semiconductor substrate 12 to form the N type semiconductor region 23, similarly to the step illustrated in FIG. 17A. Subsequently, etching is performed from the front surface S2 side of the semiconductor substrate 12 through the mask 40 to form the trench portions 25. Subsequently, as illustrated in FIG. 33A, a semiconductor crystal is epitaxially grown on the side wall surface S4 of the trench portion 25 while adding N type impurities, and the N type epitaxial growth layer 53 is formed in the trench portion 25 so as to cover the side wall surface S4 and the bottom surface of the trench portion 25. Subsequently, as illustrated in FIG. 33B, a semiconductor crystal is epitaxially grown while adding P type impurities to a surface of the N type epitaxial growth layer 53 on the center side in the width direction of the trench portion 25 (hereinafter, also referred to as a “center side surface S13”), and the P type epitaxial growth layer 54 is formed in the trench portion 25 so as to cover the center side surface S13 of the N type epitaxial growth layer 53. Thereafter, the step illustrated in FIG. 17C is omitted, and the element isolation portion 26 illustrated in FIG. 31 is formed through the steps illustrated in FIGS. 17D to 17G. Subsequently, as illustrated in FIG. 31, the insulating film 14, the light shielding film 15, the planarizing film 16, the color filter layer 18, and the microlens array 19 are formed. As a result, the solid-state imaging device 1 illustrated in FIG. 31 is manufactured.

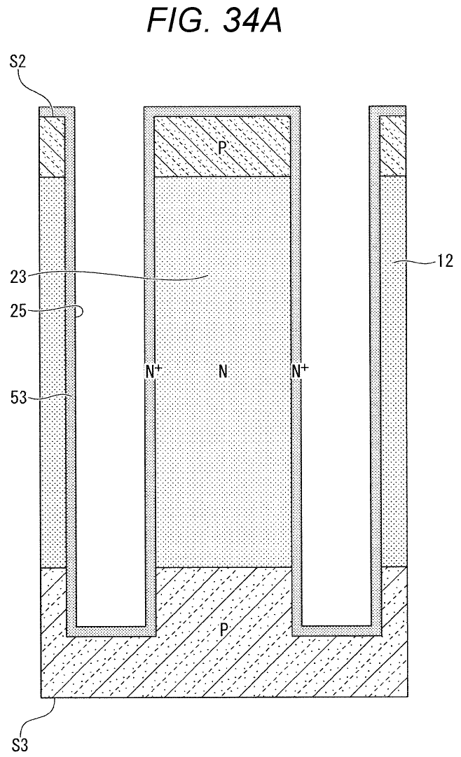

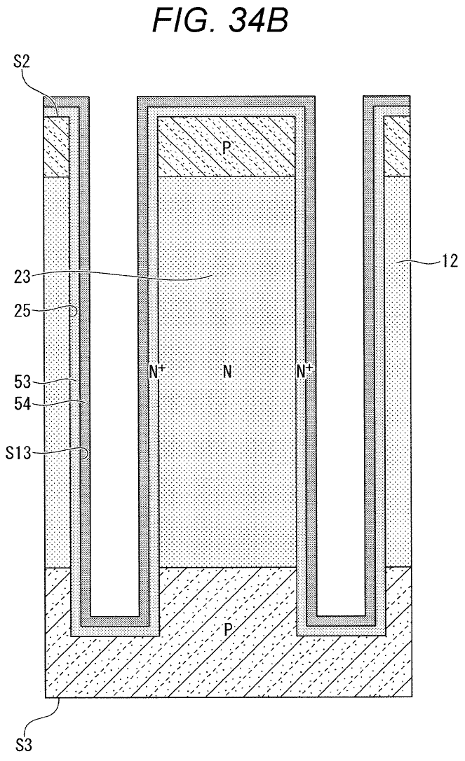

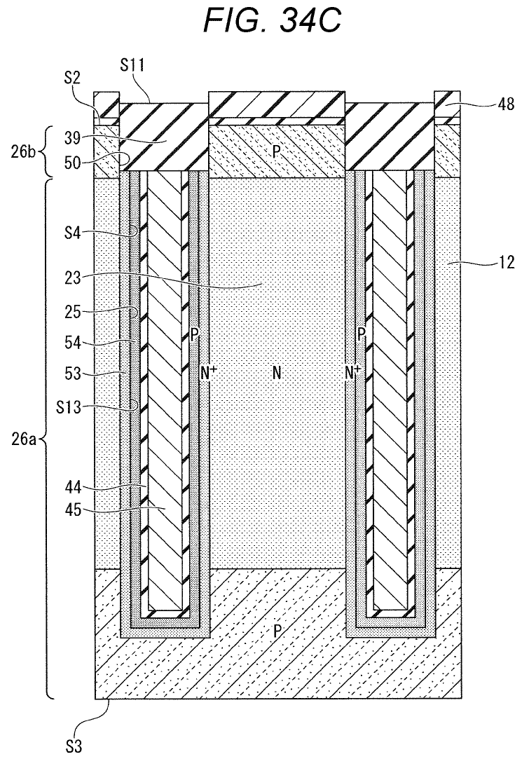

Furthermore, in a case of adopting a manufacturing method similar to the method for manufacturing the solid-state imaging device 1 illustrated in FIGS. 18A to 18I, first, N type impurities are ion-implanted into the P type semiconductor substrate 12 to form the N type semiconductor region 23, similarly to the step illustrated in FIG. 18A. Subsequently, etching is performed from the front surface S2 side of the semiconductor substrate 12 through a mask (not illustrated) to form the trench portions 25. Subsequently, as illustrated in FIG. 34A, a semiconductor crystal is epitaxially grown while adding N type impurities to the side wall surface S4 or the like of the trench portion 25, and the N type epitaxial growth layer 53 is formed in the trench portion 25 and on the front surface S2 of the semiconductor substrate 12 so as to continuously cover the entire side wall surface S4 and the bottom surface of the trench portion 25 and the front surface S2 of the semiconductor substrate 12. Subsequently, as illustrated in FIG. 34B, a semiconductor crystal is epitaxially grown on the surface (center side surface S13) or the like of the N type epitaxial growth layer 53 on the center side in the width direction of the trench portion 25 while adding P type impurities, and the P type epitaxial growth layer 54 is formed in the trench portion 25 or the like so as to continuously cover the entire center side surface S13 of the N type epitaxial growth layer 53. Thereafter, the step illustrated in FIG. 18C is omitted, and the steps illustrated in FIGS. 18D to 18I are performed to form the element isolation portion 26 illustrated in FIG. 34C. Note that, as illustrated in FIG. 34C, the configuration of the second element isolation portion 26b formed by this manufacturing method is slightly different from the configuration of the second element isolation portion 26b formed by the above manufacturing method (the configuration of the second element isolation portion 26b in FIG. 31). Subsequently, as illustrated in FIG. 31, the insulating film 14, the light shielding film 15, the planarizing film 16, the color filter layer 18, and the microlens array 19 are formed. As a result, the solid-state imaging device 1 illustrated in FIG. 31 is manufactured.

### 4-3 Modification

(1) Note that the present technology can be applied to all photodetection devices including, in addition to the solid-state imaging device 1 as the image sensor described above, a distance measuring sensor which is also called a time of flight (ToF) sensor and measures a distance, and the like. The distance measuring sensor is a sensor that emits irradiation light toward an object, detects reflected light that is the irradiation light reflected off a surface of the object, and calculates a distance to the object on the basis of a flight time from the emission of the irradiation light to the reception of the reflected light. As a light receiving pixel structure of the distance measuring sensor, the above-described structure of the pixel 8 can be adopted.

### 5. FIFTH EMBODIMENT: APPLICATION EXAMPLE TO ELECTRONIC DEVICE

The technology (present technology) according to the present disclosure may be applied to various electronic devices.

FIG. 35 is a diagram illustrating an example of a schematic configuration of an imaging device (video camera, digital still Camera, or the like) as an electronic device to which the present technology is applied.

As illustrated in FIG. 35, an imaging device 1000 includes the lens group 1001, a solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to each other via a bus line 1007.

The lens group 1001 guides incident light (image light) from a subject to the solid-state imaging device 1002, and forms an image on a light incident surface (pixel region) of the solid-state imaging device 1002.

The solid-state imaging device 1002 includes the CMOS image Sensor of the first embodiment described above. The solid-state imaging device 1002 converts the light amount of the incident light imaged on the light incident surface by the lens group 1001 into an electric signal in units of pixels and supplies the electric signal to the DSP circuit 1003 as a pixel signal.

The DSP circuit 1003 performs predetermined image processing on the pixel signal supplied from the solid-state imaging device 1002. Then, the DSP circuit 1003 supplies image signals for each frame, the image signals having been subjected to the image processing, to the frame memory 1004 to temporarily store the image signals in the frame memory 1004.

The monitor 1005 includes, for example, a panel type display device such as a liquid crystal panel or an organic electro luminescence (EL) panel. The monitor 1005 displays the image (moving image) of the subject on the basis of the pixel signal for each frame temporarily stored in the frame memory 1004.

The memory 1006 includes a DVD, a flash memory, or the like. The memory 1006 reads and records the pixel signals of each frame temporarily stored in the frame memory 1004.

Note that the electronic device to which the solid-state imaging device 1 can be applied is not limited to the imaging device 1000, and can also be applied to other electronic devices. Furthermore, the solid-state imaging device 1 according to the first embodiment is used as the solid-state imaging device 1002, but other configurations can also be employed. For example, another photodetection device to which the present technology is applied, such as the solid-state imaging device 1 according to each of the second to fourth embodiments and the solid-state imaging device 1 according to each of the modified examples of the second to fourth embodiments, may be used.

Note that the present disclosure may also have the following configurations.
(1)

A photodetection device including:
a semiconductor substrate on which a plurality of photoelectric conversion units is formed; and
an element isolation portion including a trench portion formed between the photoelectric conversion units in the semiconductor substrate, a semiconductor layer disposed in the trench portion and covering a side wall surface of the trench portion, and a functional layer disposed in a space inside the trench portion covered with the semiconductor layer, in which
the photoelectric conversion unit has an N type semiconductor region in a region in contact with the semiconductor layer,
the semiconductor layer has a P type impurity concentration of 1e16/cm³ or less, and
the functional layer is a layer that induces a hole on a side of the functional layer of the semiconductor layer.
(2)

The photodetection device according to (1), in which
the N type semiconductor region has a peak of an N type impurity concentration at an interface between the semiconductor layer and the N type semiconductor region.
(3)

The photodetection device according to (1) or (2), in which
the functional layer is a fixed charge film which is disposed along a surface on a side farther from a side wall surface of the trench portion in a surface of the semiconductor layer and has a negative fixed charge.
(4)

The photodetection device according to (1) or (2), in which
the functional layer is a conductor portion which is disposed along a surface on a side farther from a side wall surface of the trench portion in a surface of the semiconductor layer and to which a negative bias voltage is applied.
(5)

The photodetection device according to (4), in which
the conductor portion covers a side wall surface of the trench portion so that a side wall has a space having a groove shape formed by the conductor portion inside the trench portion.
(6)

The photodetection device according to (4), in which
the semiconductor layer is a semiconductor layer formed at a timing different from that of the semiconductor substrate.
(7)

The photodetection device according to (4), in which
the semiconductor layer is an epitaxial growth layer.
(8)

A photodetection device including:
a semiconductor substrate on which a plurality of photoelectric conversion units is formed; and
an element isolation portion including a trench portion formed between the photoelectric conversion units in the semiconductor substrate, and a P type solid-phase diffusion layer disposed in the trench portion and covering a side wall surface of the trench portion, in which
the photoelectric conversion unit has an N type semiconductor region in a region in contact with the P type solid-phase diffusion layer, and
the P type solid-phase diffusion layer has an N type impurity concentration of 1e16/cm³ or less.
(9)

A photodetection device including:
a semiconductor substrate on which a plurality of photoelectric conversion units is formed; and
an element isolation portion including a trench portion formed between the photoelectric conversion units in the semiconductor substrate, an N type epitaxial growth layer disposed in the trench portion and covering a side wall surface of the trench portion, and a P type epitaxial growth layer disposed in a space inside the trench portion covered with the N type epitaxial growth layer and in contact with the N type epitaxial growth layer, in which
the N type epitaxial growth layer has a P type impurity concentration of 1e16/cm³ or less, and
the P type epitaxial growth layer has an N type impurity concentration of 1e16/cm³ or less.
(10)

An electronic device including a photodetection device, the photodetection device including: a semiconductor substrate on which a plurality of photoelectric conversion units is formed; and an element isolation portion including a trench portion formed between the photoelectric conversion units in the semiconductor substrate, a semiconductor layer disposed in the trench portion and covering a side wall surface of the trench portion, and a functional layer disposed in a space inside the trench portion covered with the semiconductor layer, in which the photoelectric conversion unit has an N type semiconductor region in a region in contact with the semiconductor layer, the semiconductor layer has a P type impurity concentration of 1e16/cm³ or less, and the functional layer is a layer that induces a hole on a side of the functional layer of the semiconductor layer.
(11)

An electronic device including a photodetection device, the photodetection device including: a semiconductor substrate on which a plurality of photoelectric conversion units is formed; and an element isolation portion including a trench portion formed between the photoelectric conversion units in the semiconductor substrate, and a P type solid-phase diffusion layer disposed in the trench portion and covering a side wall surface of the trench portion, in which the photoelectric conversion unit has an N type semiconductor region in a region in contact with the P type solid-phase diffusion layer, and the P type solid-phase diffusion layer has an N type impurity concentration of 1e16/cm³ or less.
(12)

An electronic device including a photodetection device, the photodetection device including: a semiconductor substrate on which a plurality of photoelectric conversion units is formed; and an element isolation portion including a trench portion formed between the photoelectric conversion units in the semiconductor substrate, an N type epitaxial growth layer disposed in the trench portion and covering a side wall surface of the trench portion, and a P type epitaxial growth layer disposed in a space inside the trench portion covered with the N type epitaxial growth layer and in contact with the N type epitaxial growth layer, in which the N type epitaxial growth layer has a P type impurity concentration of 1e16/cm³ or less, and the P type epitaxial growth layer has an N type impurity concentration of 1e16/cm³ or less.
(13)

A method for manufacturing a photodetection device, the method including:
a step of forming a trench portion in a semiconductor substrate;
a step of forming an epitaxial growth layer having an impurity concentration of 1e16/cm³ or less on a side wall surface of the trench portion by epitaxial growth; and
a step of doping P type impurities into the epitaxial growth layer from inside the trench portion by solid-phase diffusion.
(14)

A method for manufacturing a photodetection device, the method including:
a step of forming a trench portion in a semiconductor substrate;
a step of forming an N type epitaxial growth layer having a P type impurity concentration of 1e16/cm³ or less on a side wall surface of the trench portion by epitaxial growth while adding N type impurities; and
a step of forming a P type epitaxial growth layer having an N type impurity concentration of 1e16/cm³ or less on a surface of the N type epitaxial growth layer on a center side in a width direction of the trench portion by epitaxial growth while adding P type impurities.

### REFERENCE SIGNS LIST

1 Solid-state imaging device
2 Pixel region
3 Vertical drive circuit
4 Column signal processing circuit
5 Horizontal drive circuit
6 Output circuit
7 Control circuit
8 Pixel
9 Pixel drive wire
10 Vertical signal line
11 Horizontal signal line
12 Semiconductor substrate
13 Fixed charge film
14 Insulating film
15 Light shielding film
16 Planarizing film
17 Light receiving layer
18 Color filter layer
19 Microlens array
20 Wiring layer
21 Photoelectric conversion unit
22 P type semiconductor region
23 N type semiconductor region
24 P type semiconductor region
25 Trench portion
26 Element isolation portion
27 Semiconductor layer
27a Hole inductive layer
28 Color filter
29 Microlens
30 Mask
32 Doped polysilicon
33 Insulating film
34 Conductor portion
35 Conductor portion
37 Semiconductor layer
38 P type solid-phase diffusion layer
39 Insulating material
40 Mask
41 Silicon nitride film
42 Silicon oxide film
43 Semiconductor layer
44 Silicon oxide
45 Doped polysilicon
46 Insulating material
47 Mask
48 Silicon nitride film
49 Silicon oxide film
50 Trench portion
51 N+ type semiconductor region
52 P type epitaxial growth layer
53 N type epitaxial growth layer
54 P type epitaxial growth layer
55 P type semiconductor region
1000 Imaging device
1001 Lens group
1002 Solid-state imaging device
1003 DSP circuit
1004 Frame memory
1005 Monitor
1006 Memory
1007 Bus line

1. A photodetection device comprising:
a semiconductor substrate on which a plurality of photoelectric conversion units is formed; and
an element isolation portion including a trench portion formed between the photoelectric conversion units in the semiconductor substrate, a semiconductor layer disposed in the trench portion and covering a side wall surface of the trench portion, and a functional layer disposed in a space inside the trench portion covered with the semiconductor layer, wherein
the photoelectric conversion unit has an N type semiconductor region in a region in contact with the semiconductor layer,
the semiconductor layer has a P type impurity concentration of 1e16/cm³ or less, and
the functional layer is a layer that induces a hole on a side of the functional layer of the semiconductor layer.

2. The photodetection device according to claim 1, wherein
the N type semiconductor region has a peak of an N type impurity concentration at an interface between the semiconductor layer and the N type semiconductor region.

3. The photodetection device according to claim 1, wherein
the functional layer is a fixed charge film which is disposed along a surface on a side farther from a side wall surface of the trench portion in a surface of the semiconductor layer and has a negative fixed charge.

4. The photodetection device according to claim 1, wherein
the functional layer is a conductor portion which is disposed along a surface on a side farther from a side wall surface of the trench portion in a surface of the semiconductor layer and to which a negative bias voltage is applied.

5. The photodetection device according to claim 4, wherein
the conductor portion covers a side wall surface of the trench portion so that a side wall has a space having a groove shape formed by the conductor portion inside the trench portion.

6. The photodetection device according to claim 1, wherein
the semiconductor layer is a semiconductor layer formed at a timing different from that of the semiconductor substrate.

7. The photodetection device according to claim 6, wherein
the semiconductor layer is an epitaxial growth layer.

8. A photodetection device comprising:
a semiconductor substrate on which a plurality of photoelectric conversion units is formed; and
an element isolation portion including a trench portion formed between the photoelectric conversion units in the semiconductor substrate, and a P type solid-phase diffusion layer disposed in the trench portion and covering a side wall surface of the trench portion, wherein
the photoelectric conversion unit has an N type semiconductor region in a region in contact with the P type solid-phase diffusion layer, and
the P type solid-phase diffusion layer has an N type impurity concentration of 1e16/cm³ or less.

9. A photodetection device comprising:
a semiconductor substrate on which a plurality of photoelectric conversion units is formed; and
an element isolation portion including a trench portion formed between the photoelectric conversion units in the semiconductor substrate, an N type epitaxial growth layer disposed in the trench portion and covering a side wall surface of the trench portion, and a P type epitaxial growth layer disposed in a space inside the trench portion covered with the N type epitaxial growth layer and in contact with the N type epitaxial growth layer, wherein
the N type epitaxial growth layer has a P type impurity concentration of 1e16/cm³ or less, and
the P type epitaxial growth layer has an N type impurity concentration of 1e16/cm³ or less.

10. An electronic device comprising a photodetection device, the photodetection device including: a semiconductor substrate on which a plurality of photoelectric conversion units is formed; and an element isolation portion including a trench portion formed between the photoelectric conversion units in the semiconductor substrate, a semiconductor layer disposed in the trench portion and covering a side wall surface of the trench portion, and a functional layer disposed in a space inside the trench portion covered with the semiconductor layer, wherein the photoelectric conversion unit has an N type semiconductor region in a region in contact with the semiconductor layer, the semiconductor layer has a P type impurity concentration of 1e16/cm³ or less, and the functional layer is a layer that induces a hole on a side of the functional layer of the semiconductor layer.

11. An electronic device comprising a photodetection device, the photodetection device including: a semiconductor substrate on which a plurality of photoelectric conversion units is formed; and an element isolation portion including a trench portion formed between the photoelectric conversion units in the semiconductor substrate, and a P type solid-phase diffusion layer disposed in the trench portion and covering a side wall surface of the trench portion, wherein the photoelectric conversion unit has an N type semiconductor region in a region in contact with the P type solid-phase diffusion layer, and the P type solid-phase diffusion layer has an N type impurity concentration of 1e16/cm³ or less.

12. An electronic device comprising a photodetection device, the photodetection device including: a semiconductor substrate on which a plurality of photoelectric conversion units is formed; and an element isolation portion including a trench portion formed between the photoelectric conversion units in the semiconductor substrate, an N type epitaxial growth layer disposed in the trench portion and covering a side wall surface of the trench portion, and a P type epitaxial growth layer disposed in a space inside the trench portion covered with the N type epitaxial growth layer and in contact with the N type epitaxial growth layer, wherein the N type epitaxial growth layer has a P type impurity concentration of 1e16/cm³ or less, and the P type epitaxial growth layer has an N type impurity concentration of 1e16/cm³ or less.

13. A method for manufacturing a photodetection device, the method comprising:
a step of forming a trench portion in a semiconductor substrate;
a step of forming an epitaxial growth layer having an impurity concentration of 1e16/cm³ or less on a side wall surface of the trench portion by epitaxial growth; and
a step of doping P type impurities into the epitaxial growth layer from inside the trench portion by solid-phase diffusion.

14. A method for manufacturing a photodetection device, the method comprising:
a step of forming a trench portion in a semiconductor substrate;
a step of forming an N type epitaxial growth layer having a P type impurity concentration of 1e16/cm³ or less on a side wall surface of the trench portion by epitaxial growth while adding N type impurities; and
a step of forming a P type epitaxial growth layer having an N type impurity concentration of 1e16/cm³ or less on a surface of the N type epitaxial growth layer on a center side in a width direction of the trench portion by epitaxial growth while adding P type impurities.
